(19) United States
(12) Patent Application Publication
(10) Pub. No.: US 2009/0158087 A1
(43) Pub. Date: Jun. 18, 2009

(54) SEMICONDUCTOR INTEGRATED CIRCUIT WITH MEMORY REPAIR CIRCUIT

(75) Inventors: Hideshi Maeno, Tokyo (JP); Wataru Uchida, Tokyo (JP); Michinobu Nakao, Tokyo (JP); Tatsuya Saito, Tokyo (JP); Mitsuo Serizawa, Kodaira (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP

(21) Appl. No.: 12/332,915

(22) Filed: Dec. 11, 2008

(30) Foreign Application Priority Data
Dec. 12, 2007 (JP) 2007-320981

(51) Int. Cl. G11C 29/08; G06F 11/14; G06F 11/26

(52) U.S. Cl. 714/6; 714/719; 714/718; 714/E11.113; 714/E11.159

(57) ABSTRACT

A semiconductor integrated circuit which can perform repair of at least one memory circuit in RAM, etc. and can promote improvement in the degree of integration is provided. The encoding circuit 3 receives the failure bit data fail [0]-fail [7], encodes these eight-bit failure bit data fail [7:0], and outputs four-bit (the number of compressed bits) encoded data ef [3:0] sequentially. This encoded data ef [3:0] can indicate various kinds of failure information about RAM1. The capture circuit 4 latches the encoded data ef [3:0] which satisfies a predetermined latch condition, as latch data cf [3:0]. The capture circuit 4 can perform a serial shift operation of the latch data cf [3:0], and can output serially the latch data cf [3:0] as the serial data output So.

### CROSS REFERENCES TO RELATED APPLICATIONS

The disclosure of Japanese Patent Application No. 2007-320981 filed on Dec. 12, 2007 including the specification, drawings and abstract is incorporated herein by reference in its entirety.

### BACKGROUND OF THE INVENTION

The present invention relates to a semiconductor integrated circuit having a memory circuit built in, such as RAM, and especially relates to a semiconductor integrated circuit provided with a repair function for the memory circuit.

A system LSI has many RAMs built in, and it is desirable to repair defects generated in RAMs, thereby improving a manufacturing yield of the system LSI. Since it is difficult to conduct repair analysis of RAM using a logic tester for LSI in the test process of LSI, a repair analysis circuit has been increasingly mounted in the LSI itself in order to assist the repair analysis. However, increase in scale and power consumption of the repair analysis circuit poses a problem with the increase of RAM in quantity.

As a semiconductor integrated circuit provided with the repair function of RAM in a system LSI in the related art, there is a semiconductor integrated circuit (a logical integrated circuit) disclosed by Document 1 (Japanese patent laid-open No. 2006-236551 (refer to FIG. 1, FIG. 2, and FIG. 5)), for example.

The semiconductor integrated circuit in the related art, represented by the semiconductor integrated circuit provided with the repair function of RAM disclosed by Document 1, is explained in the following.

In the semiconductor integrated circuit in the related art, the targets of repair is plural RAMs included in the various circuit blocks of LSI, and for testing these RAM, a built-in self-test (BIST) circuit, in the broad sense of the term, is mounted on LSI.

Each RAM has a spare memory column. When failure exists in the memory column of normal use (a memory column C [2] in FIG. 5 of Document 1), a failure-free memory column group including a spare memory column is selected by a selector (SLT0-SLT31 in FIG. 5 of Document 1), and the selected signal is conveyed to a desired circuit in LSI. A decoder DEC of FIG. 5 of Document 1 inputs rai [0]-rai [4] which is repair information (information indicating the position of a failure memory column), and generates a control signal so that the selector may not select the failure memory column.

The example of configuration of a BIST circuit and the contents of connection with a RAM group which has a spare memory column is illustrated in FIG. 1 and FIG. 2 of Document 1. The BIST circuit includes a BIST control circuit, a pattern generator, a boundary latch, a comparator, and a repair analysis circuit at least. Hereafter, operation of the repair test of RAM by the semiconductor integrated circuit in the related art is explained briefly.

(1) The inside of the boundary latch is initialized by the BIST control circuit (an internal flip-flop (FF) is set to “0”).

(2) Test pattern generation by the pattern generator is started by the BIST control circuit.

(3) An expectation value and the RAM output data are compared by the comparator during a run of the test pattern. When failure is found, among FFs of the data section of the boundary latch (hereafter, abbreviated as a “result FF”), FF of an IO bit corresponding to the failure will change its data to “1.”

(4) After the completion of the run of the test pattern, while the test result which has been stored in the result FF is read serially, repair information is generated by the repair analysis circuit provided corresponding to each RAM. Generation of the repair information rai [0]-rai [4] is performed by the sequential encoder circuit in the repair analysis circuit.

In the technology disclosed by Document 1, flip-flops (FFs) of the number of I/O bits of RAM are used for holding a comparison result; therefore, in terms of the number of FFs, the first problem that a circuit scale becomes large is induced.

FIG. 25 and FIG. 26 are circuit diagrams illustrating a test circuit portion of the data I/O unit of RAM in the related art disclosed by Document 1. FIG. 25 illustrates a data input/output controller 51 for one bit provided corresponding to RAM 50.

As illustrated in FIG. 25, one data input/output controller 51 is provided to a data input Din [i] and a data output Dout [i] which are a one-bit input/output of RAM 50. Consequently, when RAM 50 has a data input/output function of n-bits, i=1−n (“i” is one of “1” to “n”); therefore, n pieces of configuration corresponding to the data input/output controller 51 will be provided.

The data input/output controller 51 includes selectors 61 and 62, an EXOR gate G81, an AND gate G82, an OR gate G83, and a flip-flop (FF) 63.

The selector 61 receives write-in data sys_din [i] at a “0” input, write-in data bist_din [k] at a “1” input, and a mode selector control signal selmi at a control input. The selector 61 outputs RAM input data mem_din [i] which is inputted into the data input Din [i].

The EXOR gate G81 receives an expectation value cd [k] at one input, and a data output Dout [i] at another input. The AND gate G82 receives a comparison enable signal comp_en at one input, and the output of the EXOR gate G81 at another input. The OR gate G83 receives the output of the AND gate G82 at one input. The selector 62 receives a serial data input Si at a “1” input, the output of the OR gate G83 at a “0” input, and a serial shift control signal sdr at a control input. The flip-flop 63 receives the output of the selector 62 at an input terminal, and outputs a serial data output So which is returned to another input of the OR gate G83. The data output Dout [i] is outputted as read-out data sys_dout [i].

In such configuration, the selector 61 is provided in the preceding stage of the data input Din [i] of RAM 50. The write-in data sys_din [i] at the system side input and the write-in data bist_din [k] at the BIST side input are switched by the mode selector control signal selmi.

The data output Dout [i] of RAM 50 is given to a comparator circuit (EXOR gate G81 plus AND gate G82), and coincidence/no-coincidence of the expectation value cd [k] and the data output Dout [i] is determined by the comparator circuit. When the comparison enable signal comp_en is “1”, the comparison result of the expectation value cd [k] and the data output Dout [i] can be obtained in terms of the output of the AND gate G82.

That is, when the expectation value cd [k] and the data output Dout [i] disagree at the time of the comparison enabled with the comparison enable signal comp_en of “1”, the AND gate G82 generates “1” as the output.

The comparison result is held by a loop circuit which includes the OR gate G83, the selector 62, and the flip-flop 63.

However, it is necessary to initialize to “0” the comparison result held at the flip-flop 63 by setting a serial shift control signal sdr to “1”, and shifting “0” from a serial data input Si to the flip-flop 63 before the test starts.

The serial shift control signal sdr is set to “0” before the test starts, and the configuration of the loop circuit is validated. When the comparison enable signal comp_en is “0”, even if a clock (not shown) is inputted into the flip-flop 63, the storing value of the flip-flop 63 does not change.

At the time of the test, a clock is supplied to the flip-flop 63, together with the expectation value cd [k], which is a test expectation value, and the comparison enable signal comp_en of “1”, from a not-shown pattern generation circuit (corresponding to the pattern generation circuit 120 of FIG. 1). When failure is detected even once during the test (when the comparison result as the output of the AND gate G82 is set to “1”), the output of the OR gate G83 is set to “1”, and the value “1” is held in the loop circuit.

Although FIG. 25 illustrates the basic circuit, a circuit which has improved the basic circuit, as illustrated in FIG. 26, is employed in Document 1.

As illustrated in FIG. 26, one data input/output controller 52 is provided to the one-bit input/output of RAM 50, that is, the data input Din [i] and the data output Dout [i].

The data input/output controller 52 further has selectors 64 and 65, in addition to the selectors 61 and 62, the EXOR gate G81, the AND gate G82, the OR gate G83, and the flip-flop 63.

The selector 64 receives a RAM input data mem_din [i] which is the output of the selector 61 at a “0” input, the output of the selector 62 at a “1” input, and a capture control signal Irs at a control input. The output of the selector 64 is fed to the input terminal of the flip-flop 63.

The selector 65 receives the output of the flip-flop 63 at a “1” input, the data output Dout [i] at a “0” input, and a mode selector control signal selmo at a control input. The output of the selector 65 is outputted as the read-out data sys_dout [i], and also fed to another input of the EXOR gate G81. Since the remaining configuration is the same as that of the selector 61 illustrated in FIG. 25, the explanation thereof is omitted.

In such configuration, the data input/output controller 52 can perform operation equivalent to that of the data input/output controller 51, when the capture control signal Irs is set to “1” and the mode selector control signal selmo is set to “0.” Furthermore, the data input/output controller 52 can perform the following operation.

The data input/output controller 52 is utilizable for a scan test of a logic circuit. In particular, at the time of the scan test, it is possible that the flip-flop 63 is rendered to feed the output as read-out data sys_dout [i], by setting the mode selector control signal selmo to “1.”

By setting the capture control signal Irs to “0”, the data input/output controller 52 can latch the data input Din [i] to the flip-flop 63 to monitor the data input Din [i].

In the present specification, treating the circuit configuration illustrated in FIG. 26 as the known art, the explanation will be made on the basis of the configuration of the data input/output controller 51 illustrated in FIG. 25, for simplicity of the explanation.

In FIG. 27, a data input/output controller 53 of eight-bit configuration is provided by coupling in series the data input/output controller 51 illustrated in FIG. 25, in order to meet the RAM 50 having an eight-bit configuration input/output. For the sake of explanation, only scan flip-flops SFF20-SFF23 are depicted in FIG. 27, corresponding to data inputs Din [0]-Din [3 ] and data outputs Dout [0]-Dout [3].

The scan flip-flops SFF20-SFF23 has, respectively, the same configuration as the data input/output controller 51 illustrated in FIG. 25.

However, the scan flip-flop SFF20 is provided corresponding to the data input Din [0] and the data output Dout [0]. The scan flip-flop SFF20 receives write-in data sys_din [0], write-in data bist_din [0], and write-in data bist_exp [0], and outputs read-out data sys_dout [0].

Similarly, the scan flip-flop SFF2p (p=1−3) is provided corresponding to the data input Din [p] and the data output Dout [p]. The scan flip-flop SFF2p receives write-in data sys_din [p], write-in data bist_din [p], and write-in data bist_exp [p], and outputs read-out data sys_dout [p].

The scan flip-flop SFF2q (q=4−7) which is not shown in FIG. 27 is provided corresponding to the data input Din [q] and the data output Dout [q]. The scan flip-flop SFF2q receives write-in data sys_din [q], write-in data bist_din [q], and write-in data bist_exq [q], and outputs read-out data sys_dout [q].

The test write data and the test expectation value are generally grouped to two of the bits of even number and the bits of odd number (wd [0], wd [1], cd [0], cd [1]), for the purpose of reducing signal wiring.

In the example illustrated in FIG. 27, the test input data wd [1] is taken into the “1” input of the selector 61 of the scan flip-flops SFF21 and SF23 as write-in data bist_din [1] and bist_din [3]. Similarly, the test input data wd [0] is taken into the “1” input of the selector 61 of the scan flip-flops SFF20 and SF22 as write-in data bist_din [0] and write-in data bist_din [2].

The test expectation value cd [1] is fed to one input of the EXOR gate G81 of the scan flip-flops SFF21 and SF23, as write-in data bist_exp [1] and bist_exp [3]. Similarly, the test expectation value cd [0] is fed to one input of the EXOR gate G81 of the scan flip-flops SFF20 and SF22, as write-in data bist_exp [0] and bist_exp [2].

In this way, the data input/output controller 53 is required to has the scan flip-flops of the number corresponding to the number of RAM I/O (the number of input/output bits) of RAM 50.

### SUMMARY OF THE INVENTION

In the semiconductor integrated circuit described above as the related art, the internal repair analysis circuit is provided in one-to-one correspondence to RAM. Therefore, when a large number of RAMs are mounted in LSI, the problem is that the scale of the repair analysis circuit increases, causing increase of the degree of integration of a circuit.

In addition, since the data input/output controller employed as the test circuit in the related art needs to provide scanning FFs of the number corresponding to the number of RAM I/O as illustrated in FIGS. 25-27, there arises a problem of causing increase of the degree of integration of the circuit, with the increasing number of RAM I/O.

The present invention has been made in view of the above circumstances and provides a semiconductor integrated circuit in which repair of at least one memory circuit, such as RAM, mounted in the semiconductor integrated circuit is possible and the degree of integration is improved.

According to one embodiment of the present invention, an encoding circuit encodes the failure bit data of a predetermined number of bits, and obtains sequentially the encoded data of a smaller number of compressed bits than the predetermined number of bits. A capture circuit has latch circuits of the number of compressed bits, receives sequentially the encoded data of the number of compressed bits, and latches one piece of the encoded data of the number of compressed bits which satisfies a predetermined latch condition, in the latch circuits of the number of compressed bits. The encoded data of the number of compressed bits is possible to indicate first failure information on the non-existence of a failure bit and second failure information on existence of one-bit failure and the bit location at least, with respect to the data input/output of the predetermined number of bits.

According to the embodiment, it is possible for the capture circuit in a semiconductor integrated circuit to latch the encoded data of the number of compressed bits which indicates the first failure information on the non-existence of a failure bit and the second failure information on existence of one-bit failure and the bit location, only by providing the latch circuits of the number of compressed bits smaller than the number of bits of the data input/output.

Consequently, the semiconductor integrated circuit is sufficient with the configuration in which the latch circuit of the number of compressed bits smaller than the predetermined number of bits is provided to the data input/output of the predetermined number of bits. Therefore, the semiconductor integrated circuit can produce the effect that the degree of integration can be improved as much, and that the failure repair to the memory circuit with a redundancy memory can be accomplished, based on the encoded data of the number of compressed bits.

### BRIEF DESCRIPTION OF THE DRAWINGS

FIG. 1 is a block diagram illustrating the configuration of a semiconductor integrated circuit having the RAM repair function according to Embodiment 1 of the present invention;

FIG. 2 is a circuit diagram illustrating details of the internal configuration of a bridge circuit illustrated in FIG. 1;

FIG. 3 is a circuit diagram illustrating an example of the internal configuration of a repair analysis circuit illustrated in FIG. 1;

FIG. 4 is an explanatory diagram illustrating details of a repair analysis circuit and a repair decoder in the semiconductor integrated circuit according to Embodiment 1;

FIG. 5 is a wave form chart illustrating failure analysis operation by the repair analysis circuit according to Embodiment 1;

FIG. 6 is a wave form chart illustrating failure analysis operation by the repair analysis circuit according to Embodiment 1;

FIG. 7 is a wave form chart illustrating failure analysis operation by the repair analysis circuit according to Embodiment 1;

FIG. 8 is an explanatory diagram illustrating details of a repair analysis circuit and a repair decoder in a semiconductor integrated circuit according to Embodiment 2;

FIG. 9 is a wave form chart illustrating failure analysis operation by the repair analysis circuit according to Embodiment 2 of the present invention;

FIG. 10 is a wave form chart illustrating failure analysis operation by the repair analysis circuit according to Embodiment 2;

FIG. 11 is a wave form chart illustrating failure analysis operation by the repair analysis circuit according to Embodiment 2;

FIG. 12 is a block diagram illustrating the configuration of a semiconductor integrated circuit having the RAM repair function according to Embodiment 3 of the present invention;

FIG. 13 is a block diagram illustrating the configuration of a semiconductor integrated circuit having the RAM repair function according to Embodiment 4 of the present invention;

FIG. 14 is a circuit diagram illustrating the configuration of a semiconductor integrated circuit having the RAM repair function according to Embodiment 5 of the present invention;

FIG. 15 is an explanatory diagram illustrating typically input/output relation of an encoding circuit illustrated in FIG. 14;

FIG. 16 is an explanatory diagram illustrating an example of a first encoding table by the encoding circuit illustrated in FIG. 14;

FIG. 17 is an explanatory diagram illustrating an example of a second encoding table by the encoding circuit illustrated in FIG. 14;

FIG. 18 is a circuit diagram illustrating the internal configuration of first configuration of a capture circuit corresponding to the encoding circuit which performs encoding, according to the example of the first encoding table illustrated in FIG. 16;

FIG. 19 is a circuit diagram illustrating the internal configuration of second configuration of a capture circuit corresponding to the encoding circuit which performs encoding, according to the example of the first encoding table illustrated in FIG. 16;

FIG. 20 is a circuit diagram illustrating a first illustrative embodiment of a semiconductor integrated circuit having a failure analysis function, according to Embodiment 6 of the present invention;

FIG. 21 is a circuit diagram illustrating a second illustrative embodiment of the semiconductor integrated circuit having a failure analysis function, according to Embodiment 6 of the present invention;

FIG. 22 is an explanatory diagram illustrating the configuration of a semiconductor integrated circuit having a failure analysis function, according to Embodiment 7 of the present invention;

FIG. 23 is an explanatory diagram illustrating the configuration of a semiconductor integrated circuit having a failure analysis function, according to Embodiment 8 of the present invention;

FIG. 24 is an explanatory diagram illustrating the configuration of a semiconductor integrated circuit having a failure analysis function, according to Embodiment 9 of the present invention;

FIG. 25 is a circuit diagram illustrating a test circuit portion of a data I/O unit of RAM in the related art;

FIG. 26 is a circuit diagram illustrating a test circuit portion of a data I/O unit of RAM in the related art;

FIG. 27 is a circuit diagram illustrating a data input/output controller of eight-bit configuration, produced by series coupling of the data input/output controller illustrated in FIG. 25; and

FIG. 28 is an explanatory diagram illustrating the configuration of a semiconductor integrated circuit having a failure analysis function in the related art.

### DETAILED DESCRIPTION OF THE PREFERRED EMBODIMENTS

### Embodiment 1

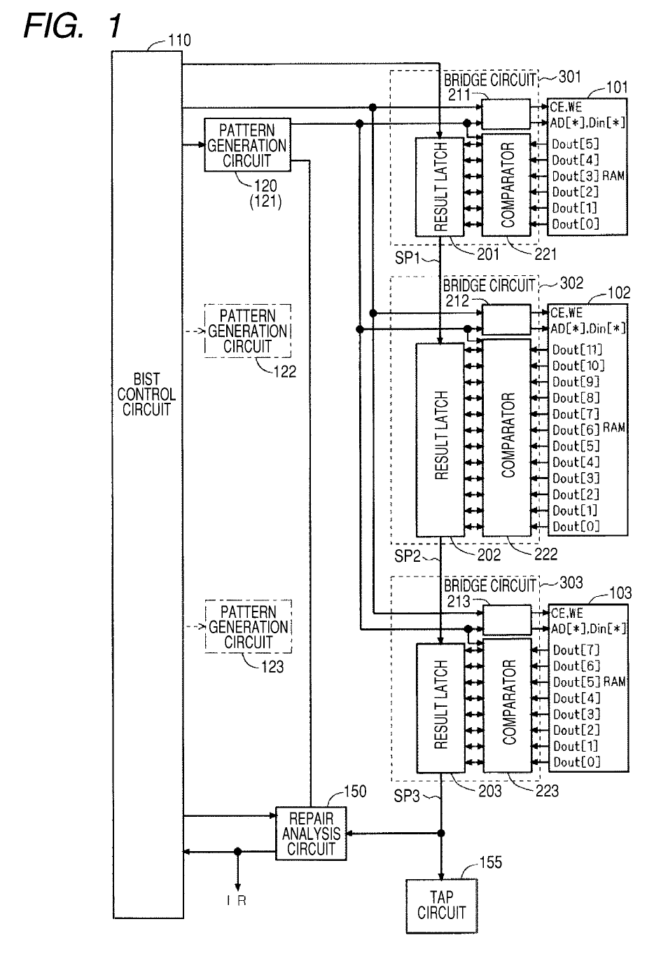

FIG. 1 is a block diagram illustrating the configuration of a semiconductor integrated circuit having the RAM repair function according to Embodiment 1 of the present invention.

As illustrated in FIG. 1, bridge circuits 301, 302, and 303 are coupled correspondingly to three RAMs 101, 102 and 103 which serve as memory circuits. RAMs 101-103 have a chip enable input CE, a write enable input WE, an address input AD [*], and a data input Din [*], respectively. In the present specification, a signal X of plural-bit configuration may simply be expressed as X [*].

RAM 101 has a six-bit data output (outputs Dout [0]-Dout [5]), RAM 102 has a 12-bit data output (outputs Dout [0]-Dout [11]), and RAM 103 has an eight-bit data output (outputs Dout [0]-Dout [7]).

The bridge circuit 301 includes a mode selector 211, a comparator 221, and a result latch 201 (a result latch unit); the bridge circuit 302 includes a mode selector 212, a comparator 222, and a result latch 202; and the bridge circuit 303 includes a mode selector 213, a comparator 223, and a result latch 203. The comparators 221-223 of the bridge circuits 301-303 have the comparison capacity corresponding to the number of data output bits of RAMs 101-103. Similarly, the result latches 201-203 have the latch capacity corresponding to the number of bits of comparators 221-223.

Among the bridge circuits 301-303, the result latches 201-203 are coupled in series. The stored data within the result latches 201-203 can be serially outputted one by one from the result latch 203, as a scan-path signal SP3 (a repair analysis scan-path signal). That is, the latch data group stored in the result latches 201-203 is detectable as the scan-path signal SP3.

A repair analysis circuit 150 performs the repair analysis operation to be explained later in full detail, based on the scan-path signal SP3, and outputs repair analysis information IR to a BIST control circuit 110 which serves as a test control circuit. The repair analysis information IR is also outputted externally, so that the repair analysis information IR can be recognized also by external devices, such as a circuit tester.

A pattern generation circuit 120 generates a test pattern (an address signal bist_ad [*], a chip enable signal bist_ce, write-in data bist_din [*], an expectation value cd [*], and a comparison enable comp_en are included) to RAMs 101-103. As illustrated in FIG. 1, the pattern generation circuit 120 may be shared among RAMs 101-103, or alternatively, as illustrated by the dashed-dotted boxes, pattern generation circuits 121-123 may be provided corresponding to RAMs 101-103 in a one-on-one relationship.

The BIST control circuit 110 controls one pattern generator (the pattern generation circuit 120) or plural pattern generators (the pattern generation circuits 121-123). The BIST control circuit 110 also controls one repair analysis circuit 150. When plural relationships exist between plural RAMs 101-103 and the repair analysis circuit 150 corresponding to the plural RAMs 101-103 as illustrate in FIG. 1, a selector group 111 can control plural circuits equivalent to the repair analysis circuit 150 by one BIST control circuit 110. There are a shift operation signal br_shift, a mode selector control signal selmi, etc. (to be described later) as the control signals which the BIST control circuit 110 outputs by itself.

The BIST control circuit 110 may control the repair analysis circuit 150 directly, or alternatively, may control the repair analysis circuit 150 indirectly via the pattern generation circuit 120.

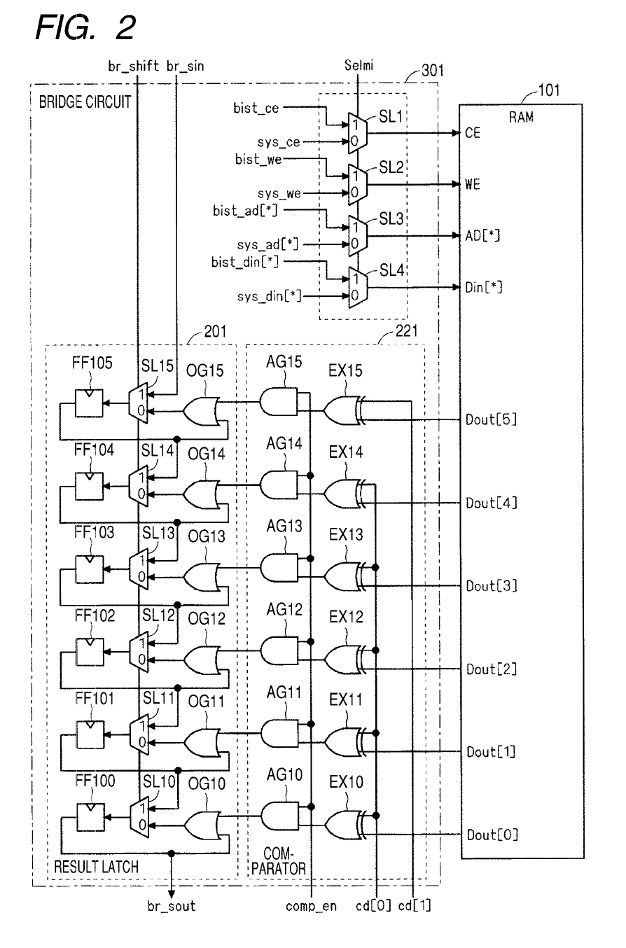

FIG. 2 is a circuit diagram illustrating details of the internal configuration of the bridge circuit 301 illustrated in FIG. 1. Hereafter, the details of the mode selector 211, the comparator 221, and the result latch 201, which are included in the bridge circuit 301, are explained with reference to FIG. 2.

The mode selector 211 includes selectors SL1-SL4. The selector SL1 receives a chip enable signal bist_ce at a “1” input, and a chip enable signal sys_ce at “0” input. The selector SL2 receives a write enable signal bist_we at a “1” input, and a write enable signal sys_we at a “0” input. The selector SL3 receives an address signal bist_ad [*] at a “1” input, and an address signal sys_ad [*] at a “0” input. The selector SL4 receives write-in data bist_din [*] at a “1” input, and write-in data sys_din [*] at a “0” input.

In this way, the selectors SL1-SL4 receive the test signal from the pattern generation circuit 120 at the “1” inputs, and receive the signal for normal operation at the “0” inputs.

When the mode selector control signal selmi is “1” indicating a test mode, the selectors SL1-SL4 select the chip enable signal bist_ce, the write enable signal bist_we, the address signal bist_ad [*], and the write-in data bist_din [*], obtained from the “1” inputs of the selectors SL1-SL4. As a result, the selectors SL1-SL4 output the selected signals to the chip enable input CE, the write enable input WE, the address input AD [*], and the data input Din [*] of RAM 101.

On the other hand, when the mode selector control signal selmi is “0” indicating a system mode, the selectors SL1-SL4 select the chip enable signal sys_ce, the write enable signal sys_we, the address signal sys_ad [*], and the write-in data sys_din [*] obtained from the “0” inputs of the selectors SL1-SL4. As a result, the selectors SL1-SL4 output the selected signals to the chip enable input CE, the write enable input WE, the address input AD [*], and the data input Din [*] of RAM 101.

The comparator 221 includes six EXOR gates EX10-EX15 and six AND gates AG10-AG15, so as to correspond to the six-bit data output Dout [0]-Dout [5].

That is, the EXOR gates EX10-EX15 receive the data output Dout [0]-Dout [5] at one input. The EXOR gates EX10, EX12, and EX14 receive an expectation value cd [0] at another input, and the EXOR gates EX11, EX13, and EX15 receive an expectation value cd [1] at another input. The expectation values cd [0] and cd [1] are generated by the pattern generation circuit 120.

The AND gates AG10-AG15 receive the outputs of the EXOR gates EX10-EX15 at one input respectively, and receive a comparison enable signal comp_en at another input in common. The output of the AND gates AG10-AG15 serves as a comparison result of the comparator 221. The comparison enable signal comp_en is outputted by the pattern generation circuit 120.

The comparator 221 of such configuration is in an active status when the comparison enable signal comp_en is “1” (“H”), and obtains, as an output of the AND gates AG10-AG15, the comparison result of the data output Dout [0]-Dout [5] and the expectation values cd [0] and cd [1] (“0” for coincidence and “1” for no-coincidence (failure occurrence)).

The result latch 201 includes six OR gates OG10-OG15, six selectors SL10-SL15, and six flip-flops FF100-FF105, so as to correspond to the six-bit comparison result.

The OR gates OG10-OG15 receive the output of the AND gates AG10-AG15 at one input. The output of the OR gates OG10-OG15 is fed to a “0” input of the selectors SL10-SL15, and the output of the selectors SL10-SL15 is fed to the data input terminal of the flip-flops FF100-FF105. The selectors SL10-SL15 receive a shift operation signal br_shift in common as a control signal. The selectors SL10-SL15 output the signal of the “1” input when the shift operation signal br_shift is “1” (“H”), and outputs the signal of the “0” input when the shift operation signal br_shift is “0” (“L”).

The output of the flip-flops FF100-FF105 is returned to another input of the OR gates OG10-OG15. The output of the flip-flops FF101-FF105 is returned to the “1” input of the selectors SL10-SL14.

A shift input signal br_sin is inputted into a “1” input of the selector SL15, the data of flip-flop FF100 is outputted externally as a shift output signal br_sout. The shift operation signal br_shift and the shift output signal br_sout are outputted from the BIST control circuit 110.

The result latch 201 of such configuration latches the comparison result from the comparator 221 (the output of the AND gates AG10-AG15) to the flip-flops FF100-FF105, when the shift operation signal br_shift is “0.” That is, once the output of the AND gate AG1i (i=0-5) is set to “1”, “1” (failure bit) is latched to a flip-flop FF10i. It is necessary to initialize the flip-flops FF100-FF105 to “0” at the time when the latch starts. In this way, the flip-flops FF100-FF105 store the comparison result from the corresponding comparator 221 as a latch data group.

On the other hand, the result latch 201 performs the serial shift operation of the shift input signal br_sin among the flip-flops FF100-FF105 coupled in series, when the shift operation signal br_shift is “1.” Namely, the shift input signal br_sin is inputted into the flip-flop FF105, the outputs of the flip-flops FF101-FF105 are respectively inputted into the flip-flops FF100-FF104, and the latch data of the flip-flop FF100 is outputted as the shift output signal br_sout. In this way, when the shift operation signal br_shift is “1”, the result latch 201 performs the serial shift operation to shift the latch data of the flip-flops FF105-FF100 one by one among the flip-flop FF100-FF105, and finally to output the latch data from the flip-flop FF100 as the shift output signal br_sout.

Using the present serial shift operation, the flip-flops FF100-FF105 can be initialized to “0” by inputting “0” into the shift input signal br_sin continuously. When the flip-flop FF105 has an asynchronous reset function or a synchronous reset function, it is also possible to initialize the flip-flops FF100-FF105 to “0” by resetting the flip-flop FF105.

The internal configuration of the bridge circuit 302 is the same as that of the bridge circuit 301 illustrated in FIG. 2. That is, the mode selector 212, the comparator 222, and the result latch 202 of the bridge circuit 302 have the same configuration as the mode selector 211, the comparator 221, and the result latch 201 of the bridge circuit 301. However, the comparator 222 and the result latch 202 are of 12-bit configuration responsively to the data output Dout [0]-Dout [11] of RAM 102.

The internal configuration of the bridge circuit 303 is also the same as that of the bridge circuit 301 illustrated in FIG. 2. That is, the mode selector 213, the comparator 223, and the result latch 203 of the bridge circuit 303 have the same configuration as the mode selector 211, the comparator 221, and the result latch 201 of the bridge circuit 301. However, the comparator 223 and the result latch 203 includes eight-bit configuration responsively to the data output Dout [0]-Dout [7] of RAM 103.

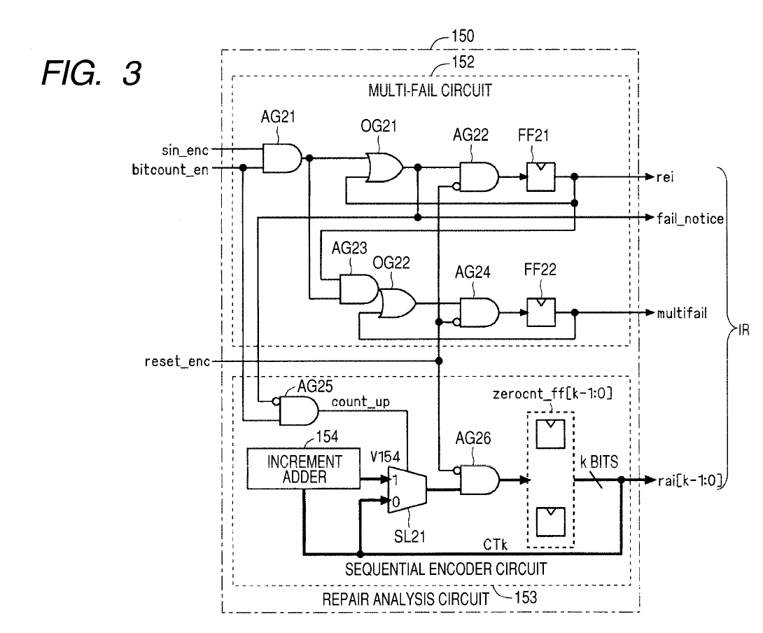

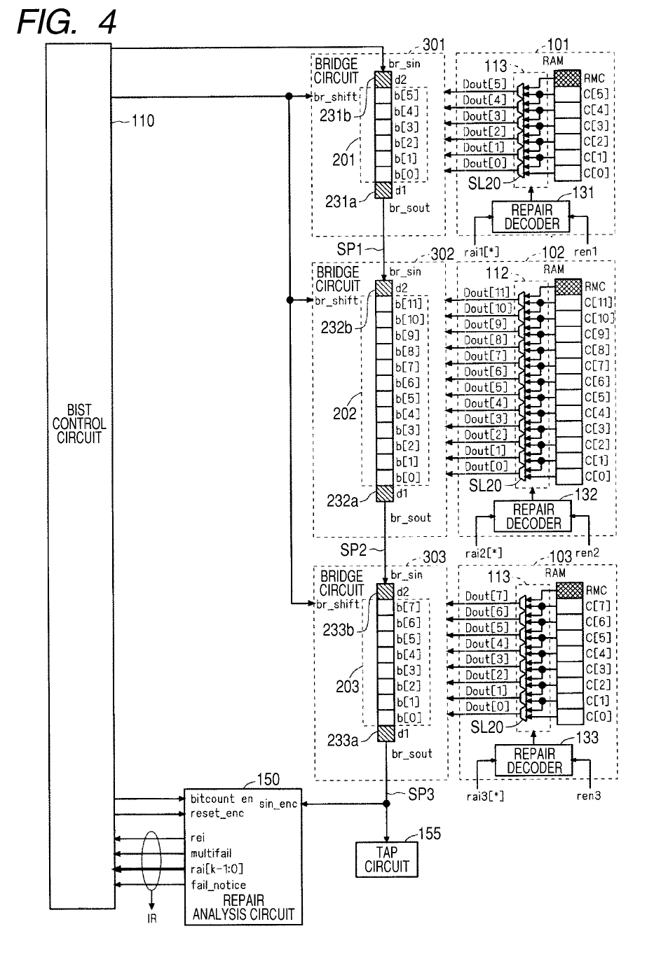

FIG. 3 is a circuit diagram illustrating an example of the internal configuration of a repair analysis circuit 150 illustrated in FIG. 1. FIG. 4 is an explanatory diagram illustrating details of the repair analysis circuit 150, the bridge circuits 301-303, RAMs 101-103, and repair decoders 131-133 in the semiconductor integrated circuit of Embodiment 1.

As illustrated in FIG. 4, the repair analysis circuit 150 receives a scan-path signal SP3 of the result latch 203 as a serial input signal sin_enc, and receives, from the BIST control circuit 110, a control signal including valid bit information bitcount_en and a reset signal reset_enc which are scan-path invalid indication signals. The repair analysis circuit 150 performs repair analysis operation based on the serial input signal sin_enc according to the control signal. The repair analysis circuit 150 then outputs repair analysis information IR including failure information rei, a multi-fail signal multifail, repair information rai [k-1:0], and a failure detection notice signal fail_notice, to the BIST control circuit 110 and the exterior.

As illustrated in FIG. 3, the repair analysis circuit 150 includes a multi-fail circuit 152 and a sequential encoder circuit 153.

The multi-fail circuit 152 includes AND gates AG21-AG24, OR gates OG21 and OG22 and flip-flops FF21 and FF22.

The AND gate AG21 receives a serial input signal sin_enc at one input, and receives a valid bit information bitcount_en at another input. The OR gate OG21 receives the output of the AND gate AG21 at one input. The output of the OR gate OG21 is fed as a failure detection notice signal fail_notice.

The AND gate AG22 receives the output of the OR gate OG21 (the failure detection notice signal fail_notice) at one input, and receives the inverted signal of a reset signal reset_enc at another input. The Flip-flop FF21 receives the output of the AND gate AG22 at an input terminal, and feeds the output as failure information rei. The failure information rei is returned to another input of the OR gate OG21.

The AND gate AG23 receives the failure information rei at one input, and receives the output of the AND gate AG21 at another input. The OR gate OG22 receives the output of the AND gate AG23 at one input. The AND gate AG24 receives the output of the OR gate OG22 at one input, and receives the inverted signal of the reset signal reset_enc at another input. The Flip-flop FF22 receives the output of the AND gate AG24 at an input terminal, and feeds the output as a multi-fail signal multifail. The multi-fail signal multifail is returned to another input of the OR gate OG22.

The multi-fail circuit 152 of such configuration, as explained in full detail later, analyzes the valid bit information among the serial input signal sin_enc (a serial input signal sin_enc at the time of bitcount_en=1). The multi-fail circuit 152 then outputs the failure information rei indicative of the existence of failure of one piece (1 bit) or more, and the multi-fail signal multifail indicative of the existence of failure two pieces (2 bits) or more. When failure is detected first, the multi-fail circuit 152 outputs a failure detection notice signal fail_notice indicating “1.”

The sequential encoder circuit 153 includes AND gates AG25 and AG26, an increment adder 154, a selector SL21, and a counting flip-flop group zerocnt_ff [k-1:0].

The AND gate AG25 receives the inverted signal of the failure detection notice signal fail_notice at one input, and receives the valid bit information bitcount_en at another input. The output of the AND gate AG25 serves as a count control signal count_up.

The increment adder 154 counts up by “1” (increments) a k-bit output CTk of the counting flip-flop group zerocnt_ff [k-1:0], and outputs a count-up output value V154. The selector SL21 receives the count-up output value V154 at a “1” input, the k-bit output CTk at a “0” input, and the count control signal count_up at a control input. The selector SL21 outputs the count-up output value V154 when the count control signal count_up is “1”, and outputs the k-bit output CTk when the count control signal count_up is “0.”

The AND gate AG26 receives the inverted signal of the reset signal reset_enc at one input, and the output of the selector SL21 at another input. Although the AND gate AG26 is shown only for one unit for the sake of explanation, the AND gate AG26 includes more units in fact so that the AND operation to the output of the selector SL21 of k bits may be performed, corresponding to the k-bit output CTk and the count-up output value V154.

The counting flip-flop group zerocnt_ff [k-1:0] includes parallel-coupled k-piece flip-flops, and latches the k-bit output of the AND gate AG26. The final k-bit output CTk of the counting flip-flop group zerocnt_ff [k-1:0] is externally fed as the repair information rai [k-1:0].

The sequential encoder circuit 153 of such configuration, as explained in full detail later, analyzes information on a valid bit (at time of bitcount_en=1) among the serial input signal sin_enc, and outputs the repair information rai [k-1:0] which indicates a failure bit position.

The multi-fail circuit 152 and the sequential encoder circuit 153 are reset by the reset signal reset_enc. When the reset signal reset_enc is “1”, the outputs of the AND gates AG22 and AG24 of the multi-fail circuit 152, and the output of the AND gate AG26 of the sequential encoder circuit 153 are set to “0.” As a result, at the next clock, the values of the failure information rei, the multi-fail signal multifail, and the repair information rai [k-1:0] are all reset to “0”.

The BIST control circuit 110 controls the bridge circuits 301-303, the pattern generation circuit 120 and the repair analysis circuit 150, performs the failure repair test of RAMs 101-103, and makes the repair analysis circuit 150 generate the repair analysis information IR.

Operation of the repair test of RAMs 101-103 performed under the control of the BIST control circuit 110 is explained in the following.

(1) Initialization within the result latches 201-203 is performed. For example, with respect to the result latch 201, the value of the flip-flops FF100-FF105 is initialized to “0.”

(2) The test pattern generation by the pattern generation circuit 120 is started.

(3) In the period of the test pattern generation by the pattern generation circuit 120, the comparators 221-223 compare the expectation value cd [*] and the data output Dout [*] of RAMs 101-103, and perform a failure detection operation. In this case, the shift operation signal br_shift is set to “0”, making the result latches 201-203 perform a latch operation to latch the comparison result detected by the comparators 221-223 as a latch data group.

The following explains an example of the comparator 221 and the result latch 201 of the bridge circuit 301. When a failure bit (a bit which has outputted a different value from the corresponding expectation value cd [*]) is found in any one of the data outputs Dout [0]-Dout [5], the output of the comparator 221 corresponding to the data output Dout [*] of the failure location is set to “1.” Assuming that the data output Dout [3] is a failure bit, the output of the AND gate AG13 is set to “1.” As a result, “1” is latched to the flip-flop FF103 among the flip-flops FF100-FF105 of the result latch 201.

(4) The test result in the flip-flops of the result latches 201-203 (the latch data group) is read out after the completion of the failure detection operation performed in the period of the test pattern generation by the comparators 221-223 and the result latches 201-203. In this case, the shift operation signal br_shift is set to “1”, making the result latches 201-203 perform a serial shift operation. As a result, the contents of three latch data groups within the result latches 201-203 are serially outputted as the scan-path signal SP3.

The following explains an example of the result latch 201 of the bridge circuit 301. By making the flip-flops FF100-FF105 perform a serial shift operation, the value of the latch data within the flip-flops FF100-FF105 can be outputted serially to the following stage as a shift output signal br_sout.

In this case, as illustrated in FIG. 4, the shift output signal br_sout of the result latch 201 is rendered to the shift input signal br_sin of the result latch 202, and the shift output signal br_sout of the result latch 202 is rendered to the shift input signal br_sin of the result latch 203. As a result, the value of the latch data groups in the result latches 201-203 can be serially obtained as the shift output signal br_sout of the result latch 203, that is, as the scan-path signal SP3.

(5) When the value of three latch data groups in the result latches 201-203 is obtained as the scan-path signal SP3, by the serial shift operation, the repair analysis circuit 150, with the contents to be explained in full detail later, generates the repair analysis information IR including the repair information rai [k-1:0], the failure information rei, the multi-fail signal multifail, and the failure detection notice signal fail_notice.

The configuration illustrated in FIG. 1 illustrates the case where RAM 101 has the data output Dout [*] of six bits, RAM 102 of 12 bits and RAM 103 of 8 bits, totaling up to 26 bits.

As illustrated in FIG. 4, in order to correspond to RAM 102 of the data output Dout [0]-Dout [11] of the maximum number of bits 12, the number of bits of the repair analysis circuit 150 employs the case of k=4. As illustrated in FIG. 4, RAMs 101-103 have a spare memory column RMC (a redundancy memory), respectively.

Repair of RAMs 101-103 is performed by supplying repair control signals (rai1 [*], ren1, rai2 [*], ren2, rai3 [*], ren3) to the repair decoders 131-133. These repair control signals are classified into the first to the third partial repair control signal. That is, the first partial repair control signal is the repair information rai1 and the repair enable signal ren1 for RAM 101 [*], the second partial repair control signal is the repair information rai2 and the repair enable signal ren2 for RAM 102 [*], and the third partial repair control signal is the repair information rai3 and the repair enable signal ren3 for RAM 103 [*].

Although explained in full detail later, the repair information rai1 [*]-rai3 [*] corresponds to the value of the counting flip-flop group zerocnt_ff [k-1:0] (k-bit output CTk) corresponding to RAMs 101-103, the value being obtained at observation timing t11-t13 from the repair analysis circuit 150. The repair enable signals ren1-ren3 correspond to the repair enable signal rei corresponding to RAMs 101-103, obtained at observation timing t11-t13 from the repair analysis circuit 150.

The repair enable signals ren1-ren3 denote repair valid by “1”, and denote repair invalid by “0”, respectively. The repair information rai1 [*]-rai3 [*] indicates the bit to be repaired (the position of the memory column C [*]) of RAMs 101-103. The repair decoders 131-133 control the selector groups 111-113 to perform the failure repair, based on the first to the third partial repair control signal. The selector groups 111-113 include selectors SL20 of the number of the data output bits plus one, respectively.

An example of the repair decoder 133 is explained in the following. The selector group 113 controlled by the repair decoder 133 includes eight selectors SL20. Each selector SL20 inputs one group of adjoining memory columns C [0] and C [1], C [1] and C [2],—C [6] and C [7], and C [7] and RMC. Each selector SL20 validates one of the adjoining memory columns under the control of the repair decoder 133, and outputs the validated one as data outputs Dout [0]-Dout [7].

When the repair enable signal ren3 is “1” and the repair information rai3 [*] denotes “0010” (“2” in decimal) in the third partial repair control signal, the repair decoder 133 controls the selector group 113 so as to disenable the memory column C [2] and to employ the spare memory column RMC. The selector group 113 is controlled to output the output of memory columns C [0] and C [1] as the data output Dout [0] and Dout [1], to output the output of the memory column C [3]-C [7] as the data output Dout [2]-Dout [6], and to output the output of the spare memory column RMC as the data output Dout [7].

As illustrated in FIG. 4, when the first to the third partial repair control signal are independent among RAMs 101-103, it is desired that the repair decoders 131-133 perform the repair control to RAMs 101-103.

In the configuration illustrated in FIG. 4, before and after each shift path (a serial input part and a serial output part) of the result latches 201-203, dummy latch units 231a-233a and 231b-233b are respectively provided, to store one dummy bit d1 and one dummy bit d2, which are irrelevant to the repair analysis.

As for an example of the result latch 201, a dummy latch unit 231b is provided on the side of the shift input signal br_sin of a valid bit b [5], and a dummy latch unit 231a is provided on the side of the shift output signal br_sout of a valid bit b [0]. The valid bits b [0]-b [5] mean the latch data of the flip-flops FF100-FF105.

The dummy latch units 231a and 231b are realizable by composing them equivalent to the selector SLli (i=0−5) and the flip-flop FF10i. It is also expected that the dummy latch units 231a and 231b are realizable by diverting a circuit section employed for another signal processing, such as the flip-flops (FF1, FF2, and FF20) illustrated in FIG. 2 and in other figures of Document 1. The dummy latch units 231a-233a, and 231b-233b may not be indispensable, and the result latches 201-203 may be directly coupled with each other.

As described above, the control signals (reset_enc, bitcount_en, and br_shift), for practicing the latch operation and serial shift operation by the result latches 201-203 and the repair operation by the repair analysis circuit 150, are outputted from the BIST control circuit 110.

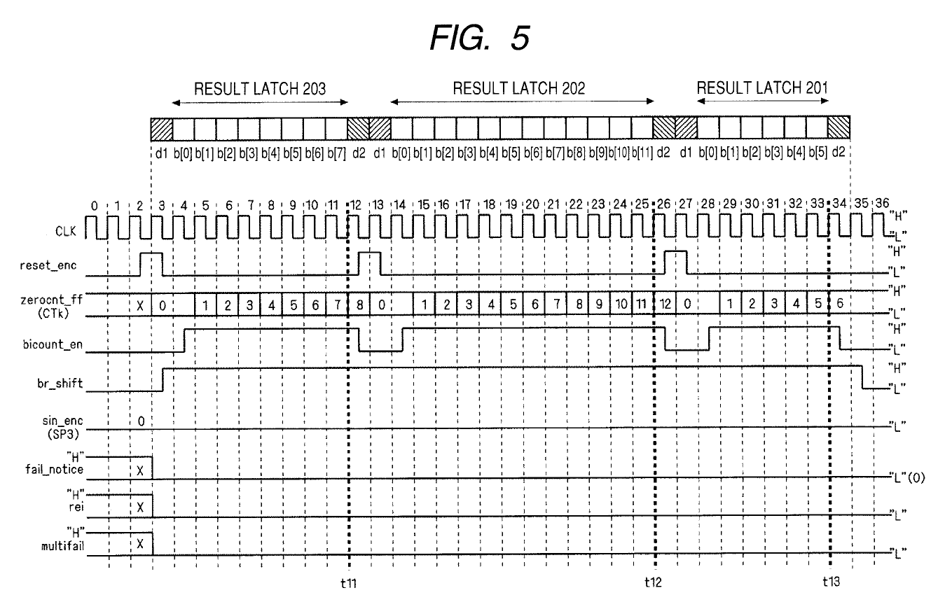

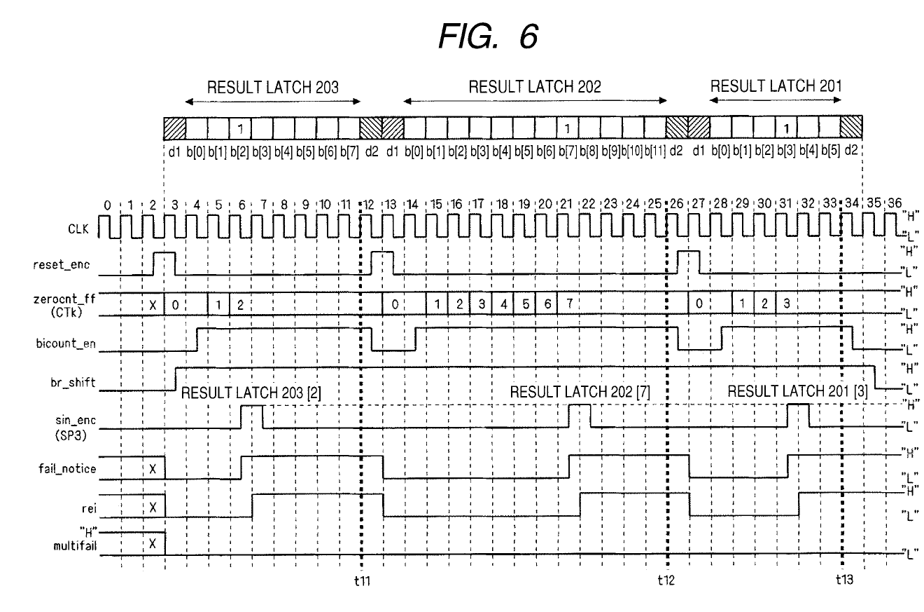

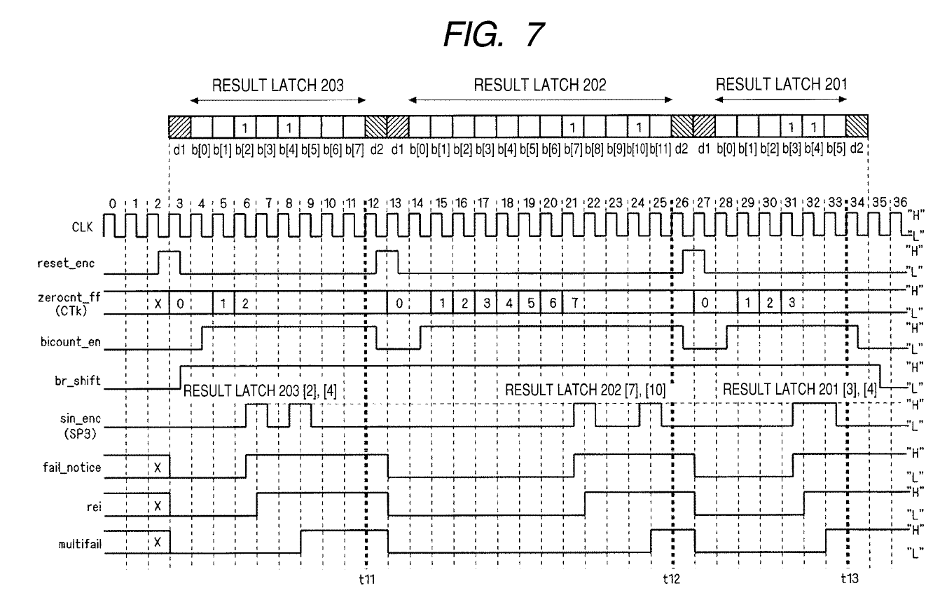

FIGS. 5-7 are wave form charts illustrating the failure analysis operation by the repair analysis circuit 150. FIG. 5 illustrates the case where there is no failure in all of RAMs 101-103. FIG. 6 illustrates the case where one-bit failure occurs in each of RAMs 101-103. FIG. 7 illustrates the case where two-bit failure occurs in each of RAMs 101-103. The operations illustrated in FIGS. 5-7 are premised on the configuration in which the dummy latch units 231a and 231b, 232a and 232b, and 233a and 233b are provided at the serial input/output parts of the result latches 201, 202, and 203 as illustrated in FIG. 4.

Although not shown in FIGS. 2-4, the flip-flops within the repair analysis circuit 150 or in the result latch 201 operate synchronizing with a clock CLK. For example, the flip-flops FF21 and FF22 take in a data input synchronizing with the up edge of the clock CLK. For the sake of explanation, in each of FIGS. 5-7, Clock Nos. 0-36 are illustrated for every cycle of the clock CLK.

First, with reference to FIG. 5, the repair analysis operation by the repair analysis circuit 150 is explained. “H” pulse of the reset signal reset_enc is generated over Clock Nos. 2-3. Then, the output of the AND gates AG22 and AG24 of the multi-fail circuit 152 are set to “0”, and the flip-flops FF21 and FF22 are initialized to “0.” Similarly, the output of the AND gate AG26 of the sequential encoder circuit 153 is set to “0”, and the k-bit output CTk (zerocnt_ff) of the counting flip-flop group zerocnt_ff [k-1:0] is initialized to “0.”

Consequently, the repair enable signal rei, the failure detection notice signal fail_notice, and the multi-fail signal multifail are initialized to “0.”

The shift operation signal br_shift is set to “1” in the period of Clock No. 3 of the clock CLK, and the serial shift operation by the flip-flops (flip-flops FF100-FF105 etc.) within the result latches 201-203 and the dummy latch units 231a and 231b-233a and 233b are started. As a result, the scan-path signal SP3 which denotes the contents of the dummy bit d1 of the bridge circuit 303 is taken into the repair analysis circuit 150 as a serial input signal sin_enc. Since the valid bit information bitcount_en is “0” at this time, the repair analysis circuit 150 determines the serial input signal sin_enc to be an invalid bit, and disregards it.

In the period of Clock No. 4 of the clock CLK, the scan-path signal SP3 which denotes the contents of the valid bit b [0] of the bridge circuit 303 is taken into the repair analysis circuit 150 as the serial input signal sin_enc. Since the valid bit information bitcount_en changes to “1” at this time, the repair analysis circuit 150 determines the serial input signal sin_enc to be a valid bit, and the count control signal count_up is set to “1”, and the count-up operation becomes effective. That is, the increment adder 154 performs a count-up operation to the k-bit output CTk, and the count-up output value V154, which denotes “1” obtained by the count-up operation, is outputted to the counting flip-flop group zerocnt_ff [k-1:0] via the selector SL21 and the AND gate AG26.

In the period of Clock No. 5 of the clock CLK, the count-up output value V154 which denotes “1” is taken into the counting flip-flop group zerocnt_ff [k-1:0], and the k-bit output CTk is counted up to “1.”

Henceforth, over Clock No. 5 to Clock No. 11 of the clock CLK, the k-bit output CTk is counted up. Since a failure bit does not exist in RAM 103, the serial input signal sin_enc maintains “0.”

At the observation timing t11 set at the up edge of Clock No. 12 of the clock CLK, the failure detection notice signal fail_notice, the repair enable signal rei, the multi-fail signal multifail, and the k-bit output CTk are observed. As a result, since the repair enable signal rei is “0”, it can be recognized that a failure bit does not exist in RAM 103. In this way, the failure detection notice signal fail_notice, the repair enable signal rei, the multi-fail signal multifail, and the k-bit output CTk which are observed at the observation timing t11 becomes the third partial repair analysis information about RAM 103, which is a part included in the repair analysis information IR.

Consequently, an external circuit tester or the BIST control circuit 110 can determine “0” (invalid) as the repair enable signal ren3, based on the repair enable signal rei of the third partial repair analysis information. In this case, the repair information rai3 [*] may be arbitrary.

Then, “H” pulse of the reset signal reset_enc is generated over Clock Nos. 12-13 of the clock CLK which is the period of generation of the dummy bits d2 and d1 located at changing of the data latch group of the result latch 203 and the data latch group of the result latch 202. Then, the flip-flops FF21 and FF22 of the multi-fail circuit 152 are initialized to “0”, and the k-bit output CTk of the counting flip-flop group zerocnt_ff [k-1:0] is initialized to “0.”

Consequently, the repair enable signal rei, the failure detection notice signal fail_notice, and the multi-fail signal multifail are again initialized to “0.”

Although the shift operation signal br_shift maintains “1” also in the period of Clock Nos. 12-13 of the clock CLK, the valid bit information bit count_en denotes “0” (invalid). Consequently, in the period of Clock Nos. 12-13 of the clock CLK, the dummy bit d2 of the bridge circuit 303 and the dummy bit d1 of the bridge circuit 302 are inputted as the serial input signal sin_enc, however, no trouble is produced in the operation of the repair analysis circuit 150.

In the period of Clock No. 14 of the clock CLK, the scan-path signal SP3 which denotes the contents of the valid bit b [0] of the bridge circuit 302 is taken into the repair analysis circuit 150 as the serial input signal sin_enc. Since the valid bit information bitcount_en is recovered to “1” at this time, the repair analysis circuit 150 determines the serial input signal sin_enc to be a valid bit, the count control signal count_up is set to “1”, and the count-up operation becomes effective.

In the period of Clock No. 15 of the clock CLK, the count-up output value V154 denoting “1” is taken into the counting flip-flop group zerocnt_ff [k-1:0], and the k-bit output CTk is counted up to “1.”

Henceforth, the k-bit output CTk is counted up over the period of Clock No. 16-Clock No. 25 of the clock CLK. Since a failure bit does not exist in RAM 102, the serial input signal sin_enc maintains “0”.

At the observation timing t12 set up at the up edge of Clock No. 26 of the clock CLK, the failure detection notice signal fail_notice, the repair enable signal rei, the multi-fail signal multifail, and the k-bit output CTk (the second partial repair analysis information) are observed. As a result, since the repair enable signal rei is “0”, it can be recognized that a failure bit does not exist in RAM 102.

Consequently, the external circuit tester or the BIST control circuit 110 can determine “0” (invalid) as the repair enable signal ren2 based on the repair enable signal rei of the second partial repair analysis information. In this case, the repair information rai2 [*] may be arbitrary.

Hereafter, in the period of Clock Nos. 27-33 of the clock CLK, the failure bit detection of RAM 101 is performed similarly.

At the observation timing t13 set up at the up edge of Clock No. 34 of the clock CLK, the failure detection notice signal fail_notice, the repair enable signal rei, the multi-fail signal multifail, and the k-bit output CTk (the first partial repair analysis information) are observed. As a result, since the repair enable signal rei is “0”, it can be recognized that a failure bit does not exist in RAM 101.

Consequently, the external circuit tester or the BIST control circuit 110 can determine “0” (invalid) as the repair enable signal ren1 based on the repair enable signal rei of the first partial repair analysis information. In this case, the repair information rai1 [*] may be arbitrary.

Next, with reference to FIG. 6, the repair analysis operation by the repair analysis circuit 150 is explained. For the sake of explanation, the same portion of operation as the operation explained in FIG. 5 is suitably omitted. The clock number of the clock CLK and the timing at which the contents of the latch data group of the result latches 201-203 are read as the serial input signal sin_enc are the same as those of FIG. 5.

Since the valid bit b [2] of the result latch 203 is “1”, the serial input signal sin_enc is set to “1” over the period of Clock Nos. 6-7 of the clock CLK. As a result, since the AND gate AG21 of the multi-fail circuit 152 is set to “1”, the failure detection notice signal fail_notice rises to “1” (“H”), synchronizing with the rising of the serial input signal sin_enc to “1.”

Then, synchronizing with the up edge of Clock No. 7 of the clock CLK, the contents of the failure detection notice signal fail_notice are latched within the flip-flop FF21. As a result, the repair enable signal rei is set to “1.”

Then, the repair enable signal rei of “1” and the failure detection notice signal fail_notice of “1” are held within the loop formed among the OR gate OG21, the AND gate AG22, and the flip-flop FF21. Therefore, the repair enable signal rei and the failure detection notice signal fail_notice maintain “1” henceforth.

As a result, since one input of the AND gate AG25 of the sequential encoder circuit 153 (an inverted signal of the failure detection notice signal fail_notice) is set to “0”, the count control signal count_up is set to “0”, and the count operation by the sequential encoder circuit 153 stops at Clock No. 6 of the clock CLK in the end.

Consequently, the k-bit output CTk is terminated by “2” latched by the counting flip-flop group zerocnt_ff [k-1:0] in the period of Clock No. 6 of the clock CLK. Henceforth, the k-bit output CTk of “2” is held by the loop formed among the selector SL21 (“0” input is selected), the AND gate AG26 and the counting flip-flop group zerocnt_ff [k-1:0]. Therefore, the k bit output CTk maintains “2” henceforth.

On the other hand, since the serial input signal sin_enc is “0” at the time of the rising of Clock No. 8 of the clock CLK, the output of the AND gate AG21 of the multi-fail circuit 152 returns to “0.” Consequently, although the repair enable signal rei fed to one input of the AND gate AG23 is “H”, the flip-flop FF22 continues latching “L”, since the valid bit information bitcount_en fed to another input is “L.” Therefore, the multi-fail signal multifail maintains the initial value of “0.”

At the observation timing t11 set up at the up edge of Clock No. 12 of the clock CLK, the failure detection notice signal fail_notice, the repair enable signal rei, the multi-fail signal multifail, and the k-bit output CTk (the third partial repair analysis information) are observed. As a result, since the repair enable signal rei is “1” and the multi-fail signal multifail is “0”, it can be recognized that a repairable bit of one-bit failure exists in RAM 103. The k-bit output CTk indicating “2” as the failure location is outputted as the repair information rai [k-1:0]. Consequently, it can be recognized that a failure bit exists in the memory column C [2] of RAM 103 by referring to the repair information rai [k-1:0].

Consequently, the external circuit tester or the BIST control circuit 110 can determine “1” (valid) as the repair enable signal ren3 based on the repair enable signal rei and the multi-fail signal multifail of the third partial repair analysis information. The repair information rai [k-1:0] can be employed as it is, as the repair information rai3 [*].

Next, the failure bit detection of RAM 102 is performed in the period of Clock Nos. 13-26 of the clock CLK.

Since the valid bit b [7] of the result latch 202 is “1”, the serial input signal sin_enc is set to “1” in the period of Clock Nos. 21-22 of the clock CLK. As a result, the failure detection notice signal fail_notice rises to “1”, synchronizing with the rising of the serial input signal sin_enc to “1.”

The repair enable signal rei is set to “1” synchronizing with the rising of Clock No. 22 of the clock CLK. Then, as described above, the repair enable signal rei and the failure detection notice signal fail_notice maintain “1.”

As a result, since one input of the AND gate AG25 of the sequential encoder circuit 153 (the inverted signal of the failure detection notice signal fail_notice) is set to “0”, the count control signal count_up is set to “0”, and the count operation by the sequential encoder circuit 153 stops at Clock No. 21 of the clock CLK in the end.

Consequently, the k-bit output CTk is terminated by “7” latched by the counting flip-flop group zerocnt_ff [k-1:0] at Clock No. 21 of the clock CLK. Henceforth, the k-bit output CTk of “7” is maintained as described above.

On the other hand, since the serial input signal sin_enc is “0” at the time of the rising of Clock No. 23 of the clock CLK, the multi-fail signal multifail maintains the initial value of “0.”

At the observation timing t12 set up at the up edge of Clock No. 26 of the clock CLK, the failure detection notice signal fail_notice, the repair enable signal rei, the multi-fail signal multifail, and the k-bit output CTk (the second partial repair analysis information) are observed. As a result, since the repair enable signal rei is “1” and the multi-fail signal multifail is “0”, it can be recognized that a repairable bit of one-bit failure exists in RAM 102. The k-bit output CTk indicating “7” as the failure location is outputted as the repair information rai [k-1:0]. By referring to the present repair information rai [k-1:0], it can be recognized that a failure bit exists in memory column C [7] of RAM 102.

Consequently, the external circuit tester or the BIST control circuit 110 can determine “1” (valid) as the repair enable signal ren2 based on the repair enable signal rei and the multi-fail signal multifail of the second partial repair analysis information. The repair information rai [k-1:0] can be employed as it is, as the repair information rai2 [*]

Hereafter, the failure bit detection of RAM 101 is performed in the period of Clock Nos. 27-33 of the clock CLK. Since “1” is latched to the valid bit b [3] of the result latch 201, similarly to the case of the result latches 203 and 202, the value of the k-bit output CTk stops by “3”, the failure detection notice signal fail_notice and the repair enable signal rei are set to “H”, and the multi-fail signal multifail maintains “L.”

At the observation timing t13 set up at the up edge of Clock No. 34 of the clock CLK, the failure detection notice signal fail_notice, the repair enable signal rei, the multi-fail signal multifail, and the k-bit output CTk (the first partial repair analysis information) are observed. As a result, since the repair enable signal rei is “1” and the multi-fail signal multifail is “0”, it can be recognized that a repairable bit of one-bit failure exists in RAM 101. The k-bit output CTk indicating “3” as the failure location is outputted as the repair information rai [k-1:0]. By referring to the present repair information rai [k-1:0], it can be recognized that a failure bit exists in memory column C [3] of RAM 101.

Consequently, the external circuit tester or the BIST control circuit 110 can determine “1” (valid) as the repair enable signal ren1 based on the repair enable signal rei and the multi-fail signal multifail of the first partial repair analysis information. The repair information rai [k-1:0] can be employed as it is, as the repair information rai1 [*].

Next, with reference to FIG. 7, the repair analysis operation by the repair analysis circuit 150 is explained. For the sake of explanation, the same portion of operation as the operation explained in FIGS. 5 and 6 is suitably omitted. The clock number of the clock CLK and the timing at which the contents of the result latches 201-203 are read as the serial input signal sin_enc are the same as those of FIGS. 5 and 6.

Since the valid bit b [2] of the result latch 203 is “1”, as explained with reference to FIG. 6, in the period of Clock Nos. 6 -7 of the clock CLK, the serial input signal sin_enc is set to “1”, and the failure detection notice signal fail_notice rises to “1”, synchronizing with the rising of the serial input signal sin_enc to “1.”

The contents of the failure detection notice signal fail_notice in the flip-flop FF21 is latched in synchronization with the rising of Clock No. 7 of the clock CLK, consequently, the repair enable signal rei is set to “1.” Then, the repair enable signal rei and the failure detection notice signal fail_notice maintain “1.” As a result, the count operation by the sequential encoder circuit 153 stops at Clock No. 6 of the clock CLK in the end.

Since the valid bit b [4] of the result latch 203 is also “1”, the serial input signal sin_enc is again set to “1” in the period of Clock Nos. 8-9 of the clock CLK.

Consequently, the serial input signal sin_enc is set to “1” at the time of rising of Clock No. 9 of the clock CLK, and the output of the AND gate AG21 of the multi-fail circuit 152 is set to “1.” Therefore, both of one input (the repair enable signal rei) and another input (the output of the AND gate AG21) of the AND gate AG23 are set to “1”, and “1” is outputted to the data input of the flip-flop FF22 via the OR gate OG22 and the AND gate AG24. Consequently, as a result of latching the data input “1” to the flip-flop FF22 at the time of rising of Clock No. 9 of the clock CLK, the multi-fail signal multifail is set to “1.”

Then, multi-fail signal multifail of “1” is held within the loop formed among the OR gate OG22, the AND gate AG24, and the flip-flop FF22. Therefore, the multi-fail signal multifail maintains “1” henceforth.

At the observation timing t11 set up at the up edge of Clock No. 12 of the clock CLK, the failure detection notice signal fail_notice, the repair enable signal rei, the multi-fail signal multifail, and the k-bit output CTk (the third partial repair analysis information) are observed. Consequently, since the multi-fail signal multifail is “1”, it can be recognized that bits of multibit failure exist in RAM 103. That is, it can be recognized that repair cannot be afforded for RAM 103.

Next, the failure bit detection of RAM 102 is performed in the period of Clock Nos. 13-26 of the clock CLK.

Since the valid bit b [7] of the result latch 202 is “1”, as explained with reference to FIG. 6, the failure detection notice signal fail_notice rises to “1”, synchronizing with the rising of the serial input signal sin_enc to “1.”

The repair enable signal rei is set to “1” synchronizing with the rising of Clock No. 22 of the clock CLK. Then, the repair enable signal rei and the failure detection notice signal fail_notice maintain “1.”

Consequently, the count control signal count_up is set to “0”, the count operation by the sequential encoder circuit 153 stops at Clock No. 21 of the clock CLK in the end, and the k-bit output CTk is fixed by “7.”

Since the valid bit b [10] of the result latch 202 is also set to “1”, in the period of Clock Nos. 24-25 of the clock CLK, the serial input signal sin_enc is again set to “1.”

Consequently, as a result that the serial input signal sin_enc is set to “1” at the time of the rising of Clock No. 25 of the clock CLK, the multi-fail signal multifail is set to “1” at the time of the rising of Clock No. 25 of the clock CLK. Then, the multi-fail signal multifail maintains “1.”

At the observation timing t12 set up at the up edge of Clock No. 26 of the clock CLK, the failure detection notice signal fail_notice, the repair enable signal rei, the multi-fail signal multifail, and the k-bit output CTk (the second partial repair analysis information) are observed. Consequently, since the multi-fail signal multifail is “1”, it can be recognized that bits of multibit failure exist in RAM 102. That is, it can be recognized that repair cannot be afforded for RAM 102.

Hereafter, in the period of Clock Nos. 27-33 of the clock CLK, the failure bit detection of RAM 101 is performed similarly. Since “1” is latched to the valid bit b [3] and b [4] of the result latch 201, similarly to the case of the result latches 203 and 202, the value of the k-bit output CTk stops by “3”, and the failure detection notice signal fail_notice, the repair enable signal rei, and the multi-fail signal multifail are set to “H.”

At the observation timing t13 set up at the up edge of Clock No. 34 of the clock CLK, the failure detection notice signal fail_notice, the repair enable signal rei, the multi-fail signal multifail, and the k-bit output CTk (the first partial repair analysis information) are observed. Consequently, since the multi-fail signal multifail is “1”, it can be recognized that bits of multibit failure exist in RAM 101. That is, it can be recognized that repair cannot be afforded for RAM 101.

In this way, the BIST control circuit 110 generates the valid bit information bitcount_en, avoiding the dummy bits d1 and d2 (invalid bits) of each of the bridge circuits 301-303 from the analytical object. Furthermore, the BIST control circuit 110 can perform the failure detection of each of the RAMs 101-103 in block in a series of the analysis processing, by generating a reset signal reset_enc of “H” before starting the repair analysis of the valid bit of each of the result latches 201-203.

At the observation timing t11-t13, the existence or nonexistence of failure of each of RAMs 101-103, the existence or nonexistence of multibit failure (failure repair cannot be afforded when it is “existence”), and a failure bit position can be recognized correctly, by observing the first to the third partial repair analysis information (fail_notice, rei, multifail, CTk (the same as zerocnt_ff: rai)).

As described above, since the semiconductor integrated circuit according to Embodiment 1 of the present invention can obtain the repair analysis information IR on plural RAMs 101-103 only by the repair analysis circuit 150 of one unit, it is possible to perform the failure repair to plural RAMs, without impairing the degree of integration.

The semiconductor integrated circuit of Embodiment 1 includes the repair decoders 131-133 corresponding to RAMs 101-103. The repair analysis information IR obtained from the repair analysis circuit 150 indicates the existence or nonexistence of the necessity of repair (rei, multifail) of each of RAMs 101-103, and the failure location (rai [k-1:0]), therefore, the failure repair can be performed independently for each of RAMs 101-103.

Furthermore, the BIST control circuit 110 in the semiconductor integrated circuit of Embodiment 1 outputs the reset signal reset_enc which indicates changes at changing of the latch data groups of the result latches 201-203 currently outputted as the scan-path signal SP3 (serial input signal sin_enc). Therefore, by suitably initializing the repair analysis operation by the repair analysis circuit 150 in terms of the reset signal reset_enc, it is possible to efficiently obtain the first to the third partial repair analysis information corresponding to the latch data group latched to the result latches 201-203, based on the scan-path signal SP3, under the control of the BIST control circuit 110.

In addition, the BIST control circuit 110 of the semiconductor integrated circuit of Embodiment 1 outputs the reset signal reset_enc in the period when the dummy bits d1 and d2 are outputted as the scan-path signal SP3. Therefore, the BIST control circuit 110 can obtain efficiently the first to the third partial repair analysis information corresponding to the latch data group of the result latches 201-203 from the repair analysis circuit 150, based on the scan-path signal SP3, without stopping a shift operation.

Since the BIST control circuit 110 outputs the valid bit information bitcount_en of “L” denoting the invalid of the scan-path signal SP3, in the period when the reset signal reset_enc is outputted, it is certainly avoidable that the failure analysis circuit 150 performs a failure analysis operation accidentally, based on the dummy data d1 and d2.

In the semiconductor integrated circuit of Embodiment 1, the result latches 201-203 can output serially plural latch data groups in the result latches 201-203 as the scan-path signal SP3, under the control based on the shift operation signal br_shift fed from the BIST control circuit 110. As a result, the repair analysis circuit 150 can obtain efficiently the repair analysis information IR including the first to the third partial repair analysis information corresponding to each of RAMs 101-103, based on the scan-path signal SP3.

Furthermore, the semiconductor integrated circuit of Embodiment 1 can recognize the existence or nonexistence of one or more failures about each of RAMs 101-103, based on the repair enable signal rei which denotes failure of one bit or more (one-bit failure information)

In addition, the semiconductor integrated circuit of Embodiment 1 can recognize the existence or nonexistence of two or more failures about each of RAMs 101-103, based on the multi-fail signal multifail which denotes failure of two bits or more. Consequently, combining with the one-bit failure information, the existence or nonexistence of repairable one failure about each of the plural RAMs 101-103 can be recognized correctly.

In Embodiment 1, the configuration is exemplified in which all of RAMs 101-103 have the repair function (spare memory column RMC), however, a RAM which does not have the repair function may be included in a part of plural RAMs.

In that case, RAM without the repair function concerned cannot be repaired, even when the repair enable signal rei is “1” and when the multi-fail signal multifail is “0”, resulting in that repair cannot be afforded as the whole LSI (semiconductor integrated circuit).

In FIG. 1, as the means that reads externally the latch information of the result latches 201-203 as the scan-path signal SP3, the TAP (Test-Access-Port) circuit 155 is illustrated. The TAP circuit illustrated in IEEE 1149.1 standard may be employed for the TAP circuit 155, for example. However, the TAP circuit 155 is not an indispensable element of the present invention.

### Embodiment 2

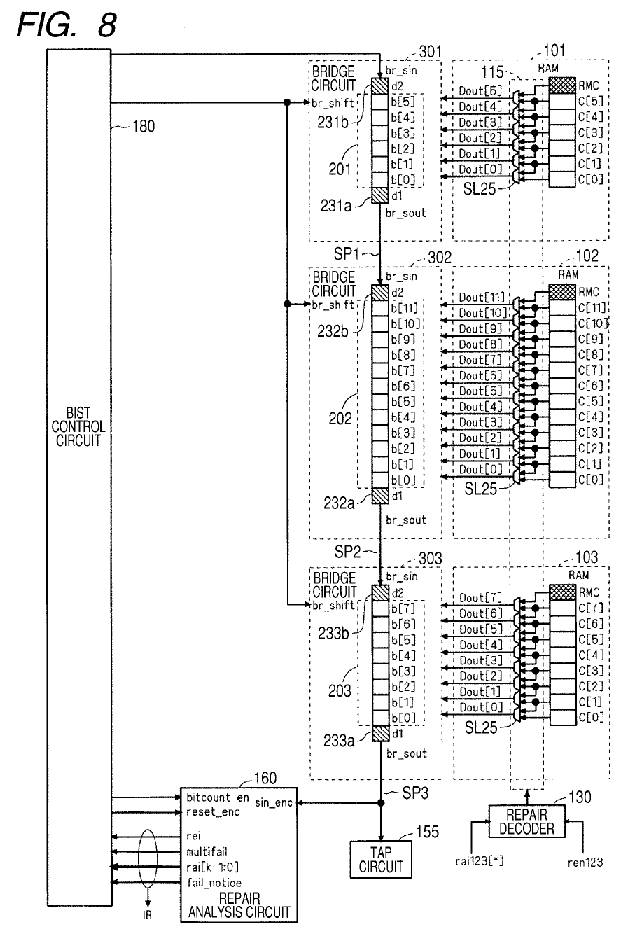

FIG. 8 is an explanatory diagram illustrating the details of a repair analysis circuit 160, bridge circuits 301-303, RAMs 101-103, and a repair decoder 130 in a semiconductor integrated circuit of Embodiment 2. The overall configuration is the same as the configuration of Embodiment 1 illustrated in FIG. 1.

As illustrated in FIG. 8, the repair analysis circuit 160 receives a scan-path signal SP3 of a result latch 203 as a serial input signal sin_enc, and inputs valid bit information bitcount_en and a reset signal reset_enc from a BIST control circuit 180. The repair analysis circuit 160 outputs repair analysis information IR which includes failure information rei, a multi-fail signal multifail, repair information rai [k-1:0], and a failure detection notice signal fail_notice to the BIST control circuit 180.

The repair analysis circuit 160 includes a multi-fail circuit 152 and a sequential encoder circuit 153 same as in the repair analysis circuit 150 of Embodiment 1 illustrated in FIG. 3.

The BIST control circuit 180 controls the bridge circuits 301-303, a pattern generation circuit 120, and the repair analysis circuit 160, to perform the failure repair control of RAMs 101-103.

In Embodiment 2, as illustrated in FIG. 8, one repair decoder 130 is provided for three RAMs 101-103 (repair control signals are rai123 [*] and ren123). Failure of one-bit I/O of one RAM among three RAMs 101-103 is set as the target of repair. Consequently, failure of two or more RAM and failure of two-bit I/O of one RAM are unrepairable.

In Embodiment 2, the total number of bits (26=6+12+8), which is the total of the number of bits of the whole RAMs 101-103, is treated as the repair information rai123 [*]. Consequently, the repair decoder 130 controls a selector group 115 which includes 26 repair selectors SL25 in RAMs 101-103. Namely, from a viewpoint of repair, three RAMs 101-103 are regarded as one RAM which has a 26-bit I/O.

In this case, it is desirable for the repair analysis circuit 160 to code each bit location of the number of bits corresponding to the total number of bits of 26. In the example of FIG. 8, the repair analysis circuit 160 of k=5 is required. Since repair analysis is performed supposing one RAM of a 26-bit I/O, it is necessary for the BIST control circuit 180 to generate a control signal corresponding to the case.

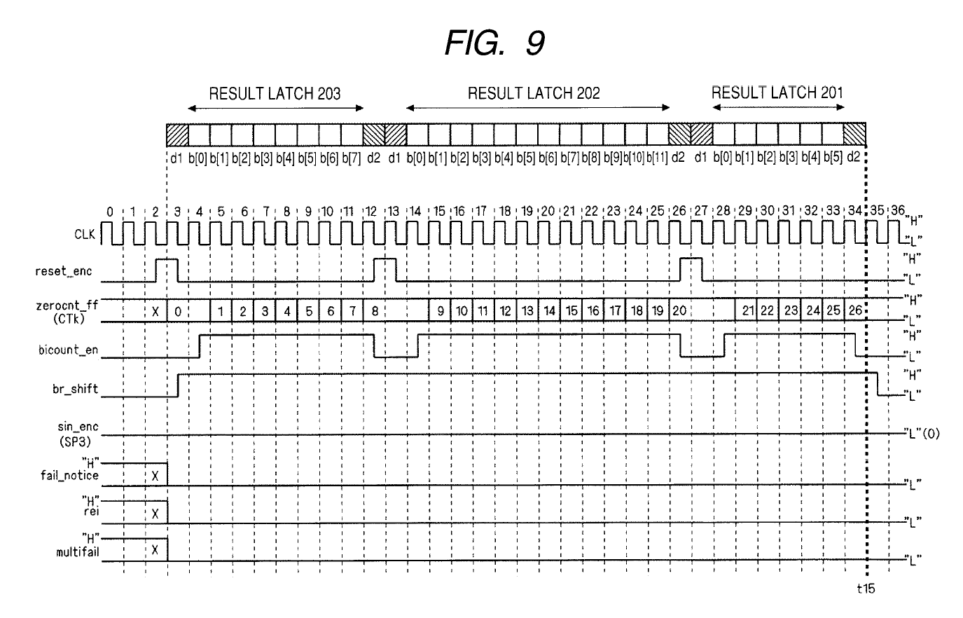

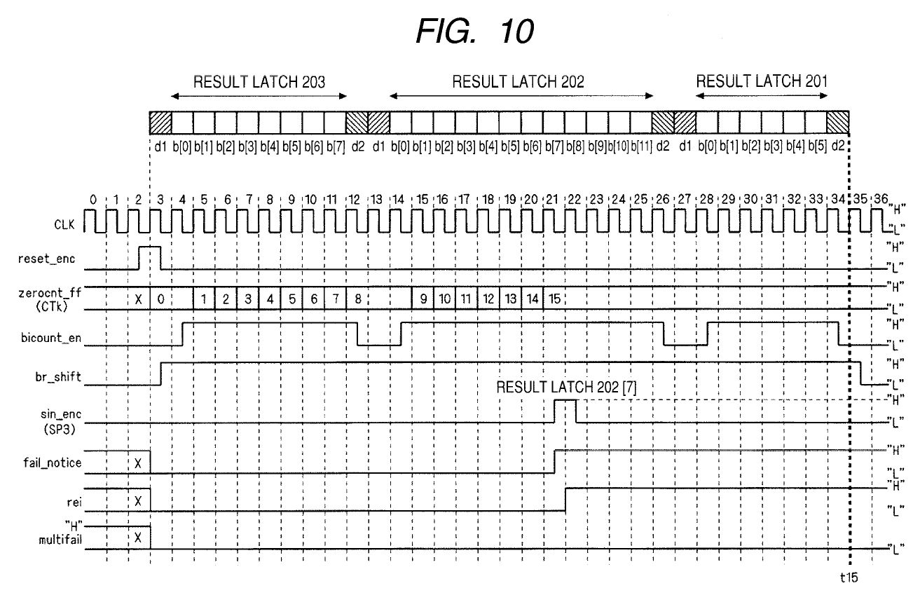

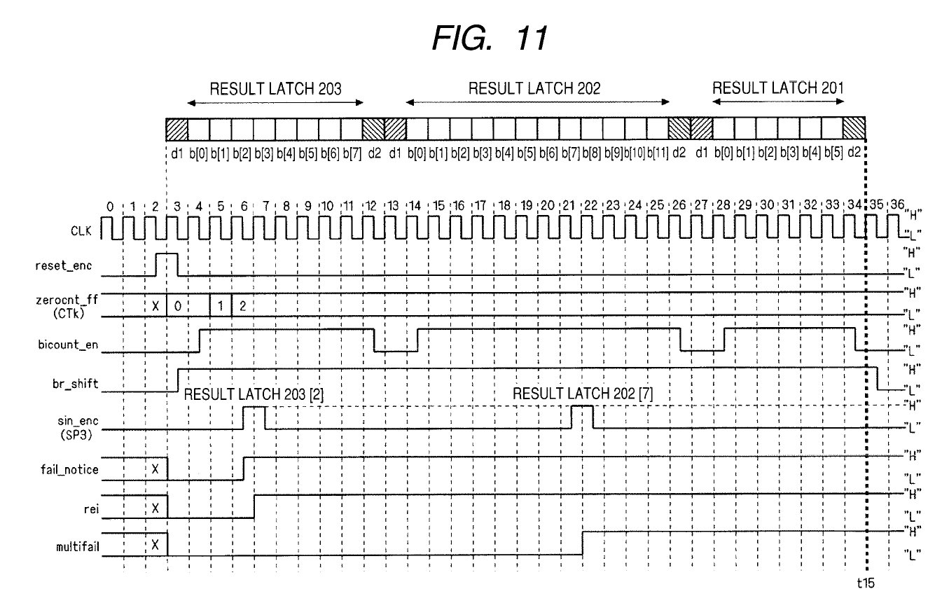

FIGS. 9-11 are wave form charts illustrating the failure analysis operation by the repair analysis circuit 160. FIG. 9 illustrates the case where there is no failure in all of RAMs 101-103. FIG. 10 illustrates the case where one-bit failure occurs in all of RAMs 101-103. FIG. 11 illustrates the case where two-bit failure occurs in all of RAMs 101-103. The operation illustrated in FIGS. 9-11 is premised on the configuration in which dummy latch units 231a and 231b, 232a and 232b, and 233a and 233b are provided in the serial input/output parts of the result latches 201, 202, and 203, respectively, as illustrated in FIG. 8.

Although not shown in FIG. 1 and FIG. 8, the flip-flops in the repair analysis circuit 160 or in the result latch 201 operate synchronizing with the clock CLK. For the sake of explanation, Clock Nos. 0-36 are illustrated for every cycle of the clock CLK in each of FIGS. 9-11.

First, with reference to FIG. 9, the repair analysis operation by the repair analysis circuit 160 is explained. “H” pulse of the reset signal reset_enc is generated over Clock Nos. 2-3. Then, as in Embodiment 1, the flip-flops FF21 and FF22 of the multi-fail circuit 152 are initialized to “0”, and the k-bit output CTk (zerocnt_ff) of the counting flip-flop group zerocnt_ff [k-1:0] is initialized to “0.”

Consequently, the repair enable signal rei, the failure detection notice signal fail_notice, and the multi-fail signal multifail are initialized to “0.”

In the period of Clock No. 3 of the clock CLK, the shift operation signal br_shift is set to “1”, and the serial shift operation among the latch data groups of the result latches 201-203 is started as in Embodiment 1. As a result, the scan-path signal SP3 which denotes the contents of the dummy bit d1 of the bridge circuit 303 is taken into the repair analysis circuit 160 as a serial input signal sin_enc. Since the valid bit information bitcount_en is “0” at this time, the repair analysis circuit 160 determines the serial input signal sin_enc to be an invalid bit, and disregards it.

In the period of Clock No. 4 of the clock CLK, the scan-path signal SP3 which denotes the contents of the valid bit b [0] of the bridge circuit 303 is taken into the repair analysis circuit 160 as the serial input signal sin_enc. Since the valid bit information bitcount_en is “1” at this time, the repair analysis circuit 160 determines the serial input signal sin_enc to be a valid bit, the count control signal count_up is set to “1”, and the count-up operation by the sequential encoder circuit 153 becomes valid, as in Embodiment 1.

Henceforth, over Clock Nos. 5-34 of the clock CLK, the k-bit output CTk is counted up. Since no failure bit exists in RAM 103, the serial input signal sin_enc maintains “0.”

In the period of Clock Nos. 12, 13 and Clock Nos. 26, 27 of the clock CLK when the dummy bits d1 and d2 are outputted, the valid bit information bitcount_en is set to “0”, thereby avoiding certainly the case that the repair analysis circuit 160 performs accidentally the repair analysis based on the dummy bits d1 and d2. Since the count control signal count_up, which is an output of the AND gate AG25 of the sequential encoder circuit 153 (refer to FIG. 3) inputting the valid bit information bitcount_en, is set to “0” in the period, the k-bit output CTk is not counted up according to the input of the dummy bits d1 and d2.

At the observation timing t15 set up at the up edge of Clock No. 35 of the clock CLK, the repair analysis information IR which includes the failure detection notice signal fail_notice, the repair enable signal rei, the multi-fail signal multifail, and the k-bit output CTk is observed. As a result, since the repair enable signal rei is “0”, it can be recognized that no failure bit exists in the whole RAMs 101-103.

Next, with reference to FIG. 10, the repair analysis operation by the repair analysis circuit 160 is explained. Explanation of the same portion of operation as the operation explained in FIG. 9 is suitably omitted for the sake of explanation. The clock number of the clock CLK and the timing at which the contents of the result latches 201-203 are read as the serial input signal sin_enc are the same as those of FIG. 9.

Since the valid bit b [7] of the result latch 202 is “1”, the serial input signal sin_enc is set to “1” over the period of Clock Nos. 21-22 of the clock CLK. Consequently, since the AND gate AG21 of the multi-fail circuit 152 is set to “1” (refer to FIG. 3), the failure detection notice signal fail_notice rises to “1”, synchronizing with the rising of the serial input signal sin_enc to “1.”

The contents of the failure detection notice signal fail_notice in the flip-flop FF21 is latched in synchronization with the rising of Clock No. 22 of the clock CLK, consequently, the repair enable signal rei is set to “1” (“H”).

Then, the repair enable signal rei and the failure detection notice signal fail_notice maintain “1” as in Embodiment 1. As a result, the count operation by the sequential encoder circuit 153 stops at Clock No. 21 of the clock CLK in the end.

Consequently, the k-bit output CTk is terminated by “15” which is latched by the counting flip-flop group zerocnt_ff [k-1:0] at Clock No. 21 of the clock CLK. Henceforth, the k-bit output CTk of “15” is maintained as in Embodiment 1.

On the other hand, since the serial input signal sin_enc is “0”, at the time of rising of Clock No. 23 of the clock CLK, the output of the AND gate AG21 of the multi-fail circuit 152 returns to “0”, as a result, the multi-fail signal multifail maintains the initial value of “0.”

At the observation timing t15 set up at the up edge of Clock No. 35 of the clock CLK, the repair analysis information IR which includes the failure detection notice signal fail_notice, the repair enable signal rei, the multi-fail signal multifail, and the k-bit output CTk is observed. As a result, since the repair enable signal rei is “1” and the multi-fail signal multifail is “0”, it can be recognized that a repairable bit of one-bit failure exists in RAMs 101-103 as a whole. The k-bit output CTk indicating “15” as the failure location is recognized as the repair information rai [k-1:0]. That is, it can be recognized that a failure bit exists in memory column C [7] (15=8+7) of the RAM 102 among RAMs 101-103 by referring to the repair information rai [k-1:0].

Next, with reference to FIG. 11, the repair analysis operation by the repair analysis circuit 160 is explained. For the sake of explanation, the same portion of operation as the operation explained in FIGS. 9 and 10 is suitably omitted. The clock number of the clock CLK and the timing at which the contents of the result latches 201-203 are read as the serial input signal sin_enc are the same as those of FIGS. 9 and 10.

Since the valid bit b [2] of the result latch 203 is “1”, the serial input signal sin_enc is set to “1”, in the period of Clock Nos. 6-7 of the clock CLK, and the failure detection notice signal fail_notice rises to “1”, synchronizing with the rising of the serial input signal sin_enc to “1.”

The contents of the failure detection notice signal fail_notice in the flip-flop FF21 is latched in synchronization with the rising of Clock No. 7 of the clock CLK, consequently, the repair enable signal rei is set to “1.” Then, the repair enable signal rei and the failure detection notice signal fail_notice maintain “1.” As a result, the count operation by the sequential encoder circuit 153 stops at Clock No. 6 of the clock CLK in the end.

Further, since the valid bit b [7] of the result latch 202 is “1”, the serial input signal sin_enc is set to “1” over the period of Clock Nos. 21-22 of the clock CLK.

Consequently, the serial input signal sin_enc is set to “1” at the time of rising of Clock No. 22 of the clock CLK, and the output of the AND gate AG21 of the multi-fail circuit 152 is set to “1” (refer to FIG. 3). Therefore, both of one input (the repair enable signal rei) and another input (the output of the AND gate AG21) of the AND gate AG23 are set to “1”, and the outputted “1” is latched to the flip-flop FF22 via the OR gate OG22 and the AND gate AG24.

Consequently, the multi-fail signal multifail is set to “1” at the time of the rising of Clock No. 22 of the clock CLK.

Then, the multi-fail signal multifail of “1” is held within the loop formed among the OR gate OG22, the AND gate AG24, and the flip-flop FF22. Therefore, the multi-fail signal multifail maintains “1” henceforth.

At the observation timing t15 set up at the up edge of Clock No. 35 of the clock CLK, the repair analysis information IR which includes the failure detection notice signal fail_notice, the repair enable signal rei, the multi-fail signal multifail, and the k-bit output CTk is observed. Consequently, since the multi-fail signal multifail is “1”, it can be recognized that a bit of multibit failure exists in RAM 103. Namely, it can be recognized that repair cannot be afforded for RAMs 101-103 as a whole.

In this way, the BIST control circuit 180 generates the valid bit information bitcount_en, avoiding the dummy bits d1 and d2 (invalid bits) of each of the bridge circuits 301-303 from the analytical object, as in the BIST control circuit 110 in Embodiment 1. The BIST control circuit 180 can perform the failure detection of the whole RAMs 101-103 in a lump, by generating the reset signal reset_enc of “H”, before the repair analysis of the valid bit of the whole result latches 201-203 starts.

When the repair analysis information (rei, multifail, and CTk (the same as zerocnt_ff: rai)) is observed at the observation timing t15, the existence or nonexistence of the failure in the whole RAMs 101-103, the existence or nonexistence of the multibit failure (failure repair cannot be afforded when it is “existence”), and the failure bit position can be recognized correctly.

In this way, the semiconductor integrated circuit according to Embodiment 2 of the present invention can conduct the repair analysis in all of the three RAMs 101-103 as in Embodiment 1, but by using one repair analysis circuit 160.

The semiconductor integrated circuit of Embodiment 2 is provided with one repair decoder 130 for the whole RAMs 101-103, and can perform the failure repair for the whole RAMs 101-103. Consequently, since the configuration is realizable in which one unit of the repair decoder 130 to RAMs 101-103 is provided, improvement in the degree of integration can be promoted more than in Embodiment 1.

The semiconductor integrated circuit of Embodiment 2 can output serially the plural latch data groups in the result latches 201-203 as the scan-path signal SP3, under the control based on the shift operation signal br_shift from the BIST control circuit 180. Consequently, the repair analysis circuit 160 can obtain efficiently the repair analysis information IR corresponding to the whole RAMs 101-103, based on the scan-path signal SP3.

In addition, the semiconductor integrated circuit of Embodiment 2 can recognize the existence or nonexistence of the failure of one or more bits about the whole RAMs 101-103 from the repair enable signal rei.

The semiconductor integrated circuit of Embodiment 2 can recognize the existence or nonexistence of the failure of two or more bits about the whole RAMs 101-103 from the multi-fail signal multifail. Consequently, combining with the repair enable signal rei, the semiconductor integrated circuit of Embodiment 2 can recognize correctly the existence or nonexistence of the failure of repairable one bit about the whole RAMs 101-103.

In Embodiment 2, the configuration is exemplified in which all of RAMs 101-103 have the repair function (spare memory column RMC), however, a RAM which does not have the repair function may be included in a part of plural RAMs.

In that case, RAM without the repair function concerned cannot be repaired, even when the repair enable signal rei is “1” and when the multi-fail signal multifail is “0”, resulting in that repair cannot be afforded as the whole LSI (semiconductor integrated circuit).

Repair of RAMs 101-103 is performed by supplying the repair control signal (rai123 [*], ren123) to the repair decoder 130. The repair information rai123 [*] corresponds to the value of the counting flip-flop group zerocnt_ff [k-1:0] (k-bit output CTk) obtained from the repair analysis circuit 160. The repair enable signal ren123 is a signal which denotes valid/invalid of repair, and is determined based on the value of the repair enable signal rei and the multi-fail signal multifail which are obtained from the repair analysis circuit 160.

The repair enable signal ren123 denotes repair valid by “1”, and denotes repair invalid by “0.” The repair information rai123 [*] indicates the bit (the position of the memory column C [*]) to be repaired of the whole RAMs 101-103. The repair decoder 131 controls the selector group 115 to perform the failure repair, based on the repair control signal. The selector group 115 is provided corresponding to the whole RAMs 101-103.

Hereafter, an example is given for explanation. When the repair enable signal ren123 is “1” and the repair information rai123 [*] denotes “01111” (15), the repair decoder 130 controls the selector group 115 to invalidate the memory column C [7] of RAM 102 (8 (the number of bits of RAM 103)+7) and to employ the spare memory column RMC of RAM 102. In particular, the selector group 115 is controlled to output, in RAM 102, the output of the memory column C [0]-C [6] as the data output Dout [0]-Dout [6], to output the output of the memory column C [8]-C [11] as the data output Dout [7]-Dout [10], and to output the output of the spare memory column RMC as the data output Dout [11]. In this case, RAM 101 and RAM 103 do not make the replacement by the spare memory column RMC. Namely, the selector group 115 is controlled, in RAM 101, to output the output of the memory column C [0]-C [5] as the data output Dout [0]-Dout [5], and in RAM 103, to output the output of the memory column C [0]-C [7] as the data output Dout [0]-Dout [7].

### Embodiment 3

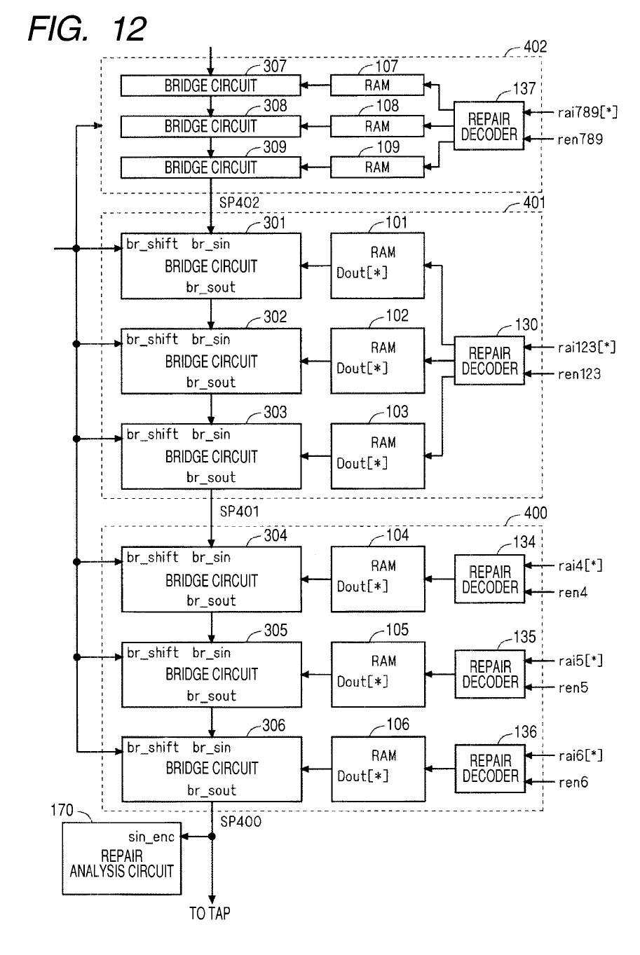

FIG. 12 is a block diagram illustrating the configuration of a semiconductor integrated circuit of Embodiment 3. The semiconductor integrated circuit of Embodiment 3 provides one repair analysis circuit 170 to RAM groups 400-402.

The RAM group 400 includes repair decoders 134-136 provided in one-to-one correspondence to RAMs 104-106 (a first-class memory circuit) and bridge circuits 304-306. The RAMs 104-106, the bridge circuits 304-306, and the repair decoders 134-136 of the RAM group 400 have relationship equivalent to the RAMs 101-103, the bridge circuits 301-303, and the repair decoders 131-133, illustrated in FIG. 1 and FIG. 4 of Embodiment 1. In addition, the bridge circuits 304-306 have the first to the third result latch unit (plural first group result latching units) and the first to the third comparator (plural first group comparators), as in the configuration illustrated in FIG. 1 and FIG. 4.

On the other hand, the RAM group 401 includes RAMs 101-103 (a second-class memory circuit), bridge circuits 301-303, and a repair decoder 130, and has the same configuration as that illustrated in FIG. 1 and FIG. 8 of Embodiment 2. The bridge circuits 301-303 have the first to the third result latch unit (plural second group result latching units) and the first to the third comparator (plural second group comparators) with the same configuration as illustrated in FIG. 1 and FIG. 8.

The RAM group 402 includes RAMs 107-109, bridge circuits 307-309, and a repair decoder 137, and has the configuration equivalent to the RAM group 401. That is, the RAMs 107-109, the bridge circuits 307-309, and the repair decoder 137 correspond to RAMs 101-103, the bridge circuits 301-303, and the repair decoder 130 of the RAM group 401.

In such configuration, the flip-flops in the bridge circuits 3.7-309, 301-303 and 304-306 are coupled in series, and the FF series coupling configuration among the RAM groups is realized. That is, a scan-path signal SP402 outputted from the bridge circuit 309 of the RAM group 402 is inputted as a shift input signal br_sin to the bridge circuit 301 of the RAM group 401. A scan-path signal SP401 outputted from th bridge circuit 303 of the RAM group 401 is inputted as a shift input signal br_sin to the bridge circuit 304 of the RAM group 400.

Consequently, when the shift operation signal br_shift is “1”, the latch data of FFs in the FF series coupling configuration among the RAM groups can be taken in, one by one, as the serial input signal sin_enc to the repair analysis circuit 170 from the scan-path signal SP400 outputted from the bridge circuit 306.

The repair analysis circuit 170 conducts the same repair analysis as the repair analysis circuit 150 of Embodiment 1, based on the valid bit b [*] of the bridge circuits 304-306, inputted as the scan-path signal SP400. The repair analysis circuit 170 obtains, as the first to the third partial repair analysis information (for the first group) corresponding to RAMs 104-106, the failure detection notice signal fail_notice, the repair enable signal rei, the multi-fail signal multifail, and the counting flip-flop group zerocnt_ff [k-1:0], respectively.

As in Embodiment 1, based on the first to the third partial repair analysis information obtained from the repair analysis circuit 170, the first to the third partial repair control signal to be supplied to the circuit repair decoders 134-136 can be obtained by the BIST control circuit or the circuit tester, which are not shown. Namely, the repair information rai4 [*] and the repair enable signal ren4 are obtained as the first partial repair control signal for the repair decoder 134; the repair information rai5 [*] and the repair enable signal ren5 are obtained as the second partial repair control signal for the repair decoder 135; and the repair information rai6 [*] and the repair enable signal ren6 are obtained as the third partial repair control signal for the repair decoder 136.

Based on the valid bit b [*] of the bridge circuits 301-303 inputted as the scan-path signal SP400, the repair analysis circuit conducts the same repair analysis as the repair analysis circuit of Embodiment 2, and obtains one kind of the repair information rai [k-1:0] and the repair enable signal rei in the RAM group 401, as repair analysis information (No. 1) for the second group. As a result, as in Embodiment 2, based on the repair analysis information (No. 1) for the second group, the repair control signal for the second group to be supplied to the repair decoder 130 (the repair information rai123 [*] and the repair enable signal ren123) can be obtained by the BIST control circuit or the circuit tester, which are not shown.

In addition, based on the valid bit b [*] of the bridge circuits 307-309 inputted as the scan-path signal SP400, the repair analysis circuit 170 conducts the same repair analysis as the repair analysis circuit 160 of Embodiment 2 and obtains one kind of the repair information rai [k-1:0] and the repair enable signal rei in the RAM group 402 as repair analysis information (No. 2) for the second group. As a result, as in Embodiment 2, based on the repair analysis information (No. 2) for the second group, the repair control signal to be supplied to the repair decoder 137 (repair information rai789 [*] and repair enable signal ren789) can be obtained by the BIST control circuit or the circuit tester, which are not shown.

In this way, the repair analysis circuits 170 in the semiconductor integrated circuit of Embodiment 3 obtains the first to the third partial repair analysis information for the first group (the RAM group 400), and the repair analysis information for the second group (the RAM groups 401 and 402). Finally, the repair control is performed for each of RAMs 104-106 by the repair decoders 134-136, and the repair control is performed for one RAM of RAMs 101-103 by the repair decoder 130, and the repair control is performed for one RAM of RAMs 107-109 by the repair decoder 137.

Namely, the repair analysis circuit 170 in the semiconductor integrated circuit of Embodiment 3 can perform the repair analysis operation to each of RAMs 104-106 in the RAM group 400, as in Embodiment 1, and in addition, can perform the repair analysis operation to the whole RAMs 101-103 in the RAM group 401, and the repair analysis operation to the whole RAMs 107-109 in the RAM group 402, as in Embodiment 2.

As a result, the repair control, the contents of which are different in the RAM group 400 as the first group, and in the RAM groups 401 and 402 as the second group, can be performed based on the repair analysis information (the first to the third partial repair control information for the first group, and the repair analysis information for the second group) obtained from one piece of the repair analysis circuit 170. That is, the repair control of different contents to RAM belonging to a different group can be effectively performed without impairing the degree of integration.

The semiconductor integrated circuit of Embodiment 3 can obtain the failure analysis information to RAMs 101-109 of the RAM groups 400-402 collectively, based on one piece of the repair analysis scan-path signal SP400.

The BIST control circuit (not shown) of Embodiment 3 has the control operation of both the BIST control circuit 110 of Embodiment 1 and the BIST control circuit 180 of Embodiment 2, in order to make it possible to perform several sorts of such repair analysis operations.

### Embodiment 4

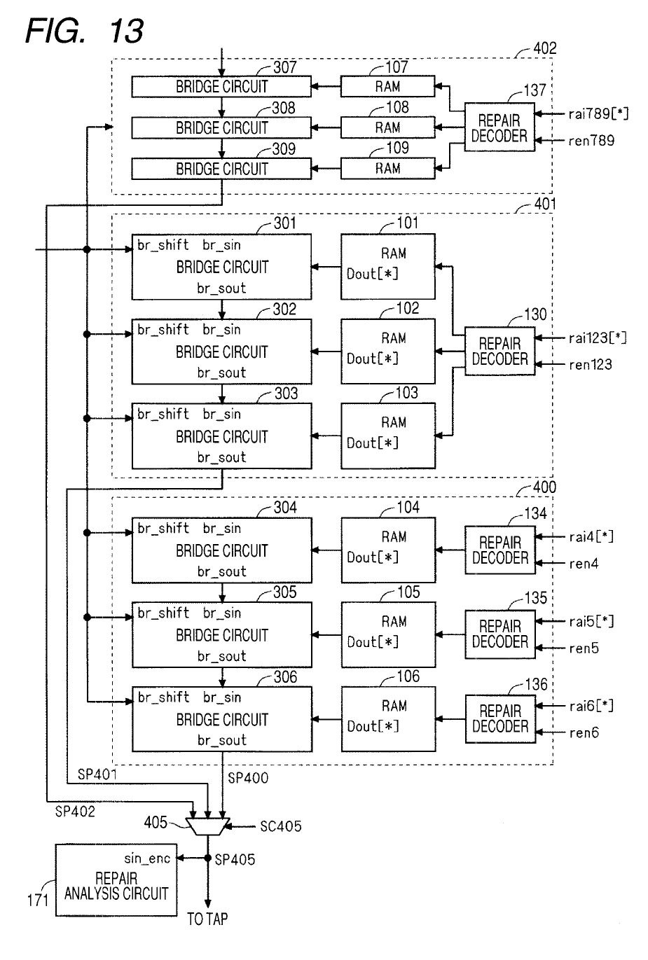

FIG. 13 is a block diagram illustrating the configuration of a semiconductor integrated circuit of Embodiment 4. The semiconductor integrated circuit of Embodiment 4 has the configuration in which one repair analysis circuit 171 is provided to RAM groups 400-402 as in Embodiment 3.

In such configuration, a scan-path signal SP402 outputted from bridge circuits 307-309, a scan-path signal SP401 outputted from bridge circuits 301-303, and a scan-path signal SP400 outputted from bridge circuits 304-306 are inputted to a selector 405.

Based on a control signal SC405 fed from a BIST control circuit (not shown), the selector 405 selects one of the scan-path signals SP400-SP402, and outputs a selection scan-path signal SP405 (a repair analysis scan-path signal). The BIST control circuit which outputs the control signal SC405 can recognize the RAM group as a repair analysis target.

The repair analysis circuit 171 takes in the selection scan-path signal SP405 as a serial input signal sin_enc, and performs a repair analysis operation.

The repair analysis operation of the repair analysis circuit 171 is explained. First, the first repair analysis operation is explained for the case where the scan-path signal SP400 is selected as the selection scan-path signal SP405.

The repair analysis circuit 171 performs the first repair analysis operation as in the repair analysis circuit 150 of Embodiment 1, based on the valid bit b [*] of the bridge circuits 304-306 inputted as the selection scan-path signal SP405. As a result, the repair analysis circuit 171 obtains, as the first to the third partial repair analysis information (for the first group) corresponding to RAMs 104-106, the failure detection notice signal fail_notice, the repair enable signal rei, the multi-fail signal multifail, and the counting flip-flop group zerocnt_ff [k-1:0], respectively. As a result, as in Embodiment 3, based on the first to the third repair analysis information for the first group, the first to the third partial repair control signal for the first group to be supplied to repair decoders 134-136 can be obtained by the BIST control circuit or the circuit tester which are not shown.

Next, the second repair analysis operation is explained for the case where the scan-path signal SP401 is selected as the selection scan-path signal SP405.

The repair analysis circuit 171 conducts the same repair analysis as the repair analysis circuit 160 of Embodiment 2, based on the valid bit b [*] of the bridge circuits 301-303, inputted as the scan-path signal SP405. The repair analysis circuit 171 obtains one kind of a failure detection notice signal fail_notice, a repair enable signal rei, a multi-fail signal multifail, and a counting flip-flop group zerocnt_ff [k-1:0] as the repair analysis information for the second group. As a result, as in Embodiment 2, based on the repair analysis information for the second group, the repair control signal for the second group (the repair information rai123 [*] and the repair enable signal ren123) to be supplied to the repair decoder 130 can be obtained by the BIST control circuit or the circuit tester, which are not shown.

Finally, the third repair analysis operation is explained for the case where the scan-path signal SP402 is selected as the selection scan-path signal SP405.

The repair analysis circuit 171 performs the third repair analysis operation, as in the repair analysis circuit 160 of Embodiment 2, that is, the repair analysis operation of the same contents as the second repair analysis operation, based on the valid bit b [*] of the bridge circuits 301-303 inputted as the selection scan-path signal SP405. The repair analysis circuit 171 obtains one kind of repair information rai [k-1:0] and a repair enable signal rei as the repair analysis information for the second group. As a result, as in Embodiment 2, based on the repair analysis information for the second group, the repair control signal for the second group to be supplied to the repair decoder 130 (the repair information rai789 [*] and the repair enable signal ren789) can be obtained by the BIST control circuit or the circuit tester.

In this way, the repair analysis circuit 171 in the semiconductor integrated circuit according to Embodiment 4 of the present invention can perform, as in the repair analysis circuit 170 of Embodiment 3, the repair analysis operation to each of RAMs 104-106 in the RAM group 400, as in Embodiment 1, and the repair analysis operation to the whole RAMs 101-103 in the RAM group 401, and the repair analysis operation to the whole RAMs 107-109 in the RAM group 402, as in Embodiment 2.

The repair analysis circuit 171 in the semiconductor integrated circuit of Embodiment 4 can selectively obtain the repair analysis information for one group among the RAM groups 400-402, based on the selection scan-path signal SP405 selected from the scan-path signals SP400-SP402. Therefore, the failure repair can be selectively performed only for the group which desires the repair analysis among the RAM groups 400-402.

In order to enable such several sorts of the repair analysis operations, the BIST control circuits (not shown) of Embodiment 4 has the control operations and the control signal SC405 to the selector 405, of both the BIST control circuit 110 of Embodiment 1 and the BIST control circuit 180 of Embodiment 2.

In Embodiment 4, the scan-path signals SP400-SP402 can be suitably selected as the selection scan-path signal SP405 by the selector 405. Therefore, by practicing selectively the first to the third repair analysis operation to the RAM groups 400-402, a repair analysis can be easily conducted only to a part of the RAM groups. For example, when practice of only the third repair analysis operation to the RAM group 402 is desired, what is necessary is to select only the scan-path signal SP402 as the selection scan-path signal SP405.

If the semiconductor integrated circuit of Embodiment 3 performs the same operation as the semiconductor integrated circuit of Embodiment 4, a dummy shift operation is necessary in order to skip the second repair analysis operation to the RAM group 401 or the first repair analysis operation to RAMs 104, 105, and 106 from the scan-path signal SP400, resulting in a complicated and time-consuming control.

On the other hand, in the semiconductor integrated circuit of Embodiment 4, such control is unnecessary and the repair analysis of the target RAM group can be conducted easily and quickly. In particular, the defect analysis can be effectively performed when many defects have occurred in only a specific RAM group.

<Others>

As described above, the repair control signal (rai1 [*], ren1, rai2 [*], ren2, rai3 [*], ren3, rai123 [*], ren123, etc.) can be obtained, based on the repair information rai [k-1:0], the repair enable signal rei, etc. as the repair analysis information. Consequently, the repair analysis information is supplied to the circuit tester via the BIST control circuit 110 (180), and the fuse circuit is formed in which a desired repair control signal is generated by the circuit tester. A register which outputs a desired repair control signal may be employed instead of the fuse circuit. Alternatively, the repair control signal itself may be outputted from the BIST control circuit 110 (180).

When the repair control signal is outputted from the BIST control circuit 110 (180), a self repair control circuit, which processes the output data of the repair analysis circuit 150 (160,170,171) and generates the repair control signal, may also be provided within the BIST control circuit 110. In this case, the so-called BISR (Built-In Self-Repair) becomes possible.

Namely, by giving a self-repair function to the semiconductor integrated circuit according to Embodiment 1-Embodiment 4, it becomes possible to internally process a series of operations to practice the self test, to conduct the repair analysis, to generate the repair control signal, and to repair RAM.

### Embodiment 5

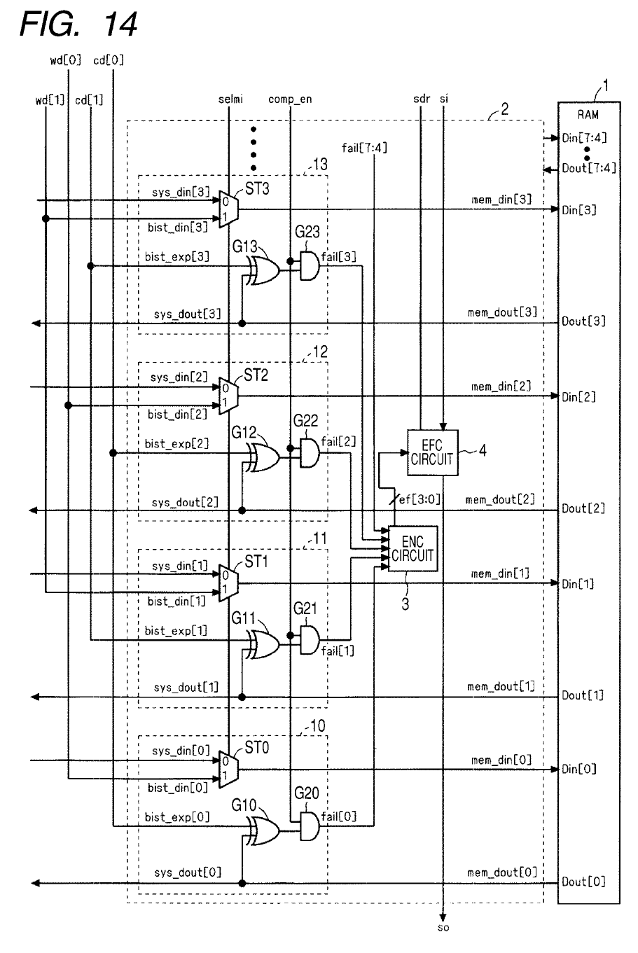

FIG. 14 is a circuit diagram illustrating the configuration of a semiconductor integrated circuit having a RAM repair function according to Embodiment 5 of the present invention. As illustrated in FIG. 14, RAM 1 has an eight-bit (the predetermined number of bits) data input/output function (the function corresponding to data inputs Din [0]-Din [7] and data outputs Dout [0]-Dout [7]). Although not shown, RAM 1 has a redundancy memory such as the spare memory column RMC illustrated in FIG. 4 of Embodiment 1, for example.

A data input/output controller 2 is provided to control the data inputs Din [0]-Din [7] and the data outputs Dout [0]-Dout [7] of RAM 1.

The data input/output controller 2 includes an encoding circuit (ENC circuit) 3, a capture circuit (EFC circuit) 4, one-bit input/output controllers 10-13 and others. For the sake of explanation, only the one-bit input/output controllers 10-13, which are provided corresponding to the data inputs Din [0]-Din [3 ] and the data outputs Dout [0]-Dout [3], are shown. In fact, a one-bit input/output controller corresponding to a data output Dout [7:4] and a data input Din [7:4] is also provided.

As illustrated in FIG. 14, the one-bit input/output controller 10 includes a selector ST0, an EXOR gate G10, and an AND gate G20.

The selector ST0 receives write-in data sys_din [0] at a “0” input, write-in data bist_din [0] at a “1” input, and a mode selector control signal selmi at a control input. The output of the selector ST0 is fed to the data input Din [0] of RAM 1 as RAM input data mem_din [0].

The EXOR gate G10 receives write-in data bist_exp [0] at one input, and receives a data output Dout [0] (a RAM output data mem_dout [0], read-out data sys_dout [0]) at another input. The AND gate G20 receives a comparison enable signal comp_en at one input, and receives the output of the EXOR gate G10 at another input. The output of the AND gate G20 is fed to the encoding circuit 3 as failure bit data fail [0].

Similarly, the one-bit input/output controller 1p (p=1−3) includes a selector STp, an EXOR gate G1p, and an AND gate G2p.

The selector STp receives write-in data sys_din [p] at a “0” input, write-in data bist_din [p] at a “1” input, and a mode selector control signal selmi in a control input. The output of the selector STp is fed to the data input Din [p] of the RAM 5p as RAM input data mem_din [p].

The EXOR gate G1p receives write-in data bist_exp [p] at one input, and receives a data output Dout [p] (RAM output data mem_dout [p], read-out data sys_dout [p]) at another input. The AND gate G2p receives a comparison enable signal comp_en at one input, and receives the output of the EXOR gate G1p at another input. The output of the AND gate G2p is fed to the encoding circuit 3 as failure bit data fail [p].

Similarly, although not shown in FIG. 14, a one-bit input/output controller 1q (q=4−7) (not shown) includes a selector STq, an EXOR gate G1q, and an AND gate G2q which are equivalent to the selector ST0, the EXOR gate G10, and the AND gate G20, respectively.

The selector STq receives write-in data sys_din [q] at a “0” input, write-in data bist_din [q] at a “1” input, and a mode selector control signal selmi in a control input. The output of the selector STq is fed to the data input Din [q] of the RAM 5q as RAM input data mem_din [q].

The EXOR gate G1q receives write-in data bist_exp [q] at one input, and receives a data output Dout [q] (RAM output data mem_dout [q], read-out data sys_dout [q]) at another input. The AND gate G2q receives a comparison enable signal comp_en at one input, and receives the output of the EXOR gate G1q at another input. The output of the AND gate G2q is fed to the encoding circuit 3 as failure bit data fail [q].

Test input data wd [1] as write-in data bist_din [1], bist_din [3], bist_din [5], and bist_din [7] ([5] and [7] are not shown) is taken into a “1” input of the selectors ST1, ST3, ST5, and ST7 (ST5 and ST7 are not shown) of the one-bit input/output controllers 11, 13, 15, and 17 (15 and 17 are not shown).

Similarly, test input data wd [0] as write-in data bist_din [0], bist_din [2], bist_din [4], and bist_din [6] ([4] and [6] are not shown) is taken into a “1” input of the selectors ST0, ST2, ST4, and ST6 (ST4 and ST6 are not shown) of the one-bit input/output controllers 10, 12, 14, and 16 (14 and 16 are not shown).

A test expectation value cd [1] as write-in data bist_exp [1], bist_exp [3], bist_exp [5], and bist_exp [7] ([5] and [7] are not shown) is fed at one input of the EXOR gate G11, G13, G15, and G17 (G15 and G17 are not shown) of the one-bit input/output controllers 11, 13, 15, and 17 (15 and 17 are not shown).

Similarly, a test expectation value cd [0] as write-in data bist_exp [0], bist_exp [2], bist_exp [4], and bist_exp [6] ([4] and [6] are not shown) is fed at one input of the EXOR gate G10, G12, G14, and G16 (G14 and G16 are not shown) of the one-bit input/output controllers 10, 12, 14, and 16 (14 and 16 are not shown).

In this way, the test write data (wd [0], wd [1]) and the test expectation value (cd [0], cd [1]) are grouped into two of the input/output bits (“i” of the data output Dout [i] and the data input Din [i]) of even numbers and odd numbers, in order to reduce the number of signal wiring.

In the one-bit input/output controllers 10-17 of such configuration, in cases where the comparison enable signal comp_en is “1”, when the no-coincidence of write-in expectation value bist_ext [i] (i=0−7) and the data output Dout [i] is detected by the comparison circuit (the EXOR gate G1i and the AND gate G2i), “1” is outputted as failure bit data fail [i]. On the other hand, when the no-coincidence is not detected by the comparison circuit, the failure bit data fail [i] is set to “0.”

The failure bit data fail [i] which indicates the comparison result by the comparison circuit is obtained sequentially in the period when the test pattern is generated, similarly to the case of the semiconductor integrated circuit of Embodiment 1. That is, the failure bit data fail [0]-fail [7] are obtained sequentially by supplying the test write data (wd [0], wd [1]) sequentially, and comparing the data output Dout [i] with the corresponding test expectation value (cd [0], cd [1]) sequentially. In Embodiment 5, although not explained in full detail, the test input data wd [0] and wd [1] and the expectation values cd [0] and cd [1] are outputted sequentially by the pattern generation circuit as in Embodiment 1.

The encoding circuit 3 receives the failure bit data fail [0]-fail [7], encodes these eight-bit failure bit data fail [7:0], and outputs four-bit (the number of compressed bits) encoded data ef [3:0] one by one. The first to the third failure information of RAM 1 (described later) can be indicated by the encoded data ef [3:0].

The capture circuit 4 receives a serial data input Si, a serial shift control signal sdr, and the encoded data ef [3:0], and latches the encoded data ef [3:0] which satisfies the latch condition (a predetermined condition) described later, as latch data cf [3:0].

The capture circuit 4 can perform a serial shift operation of the latch data cf [3:0], and can serially output the latch data cf [3:0] as a serial data output So.

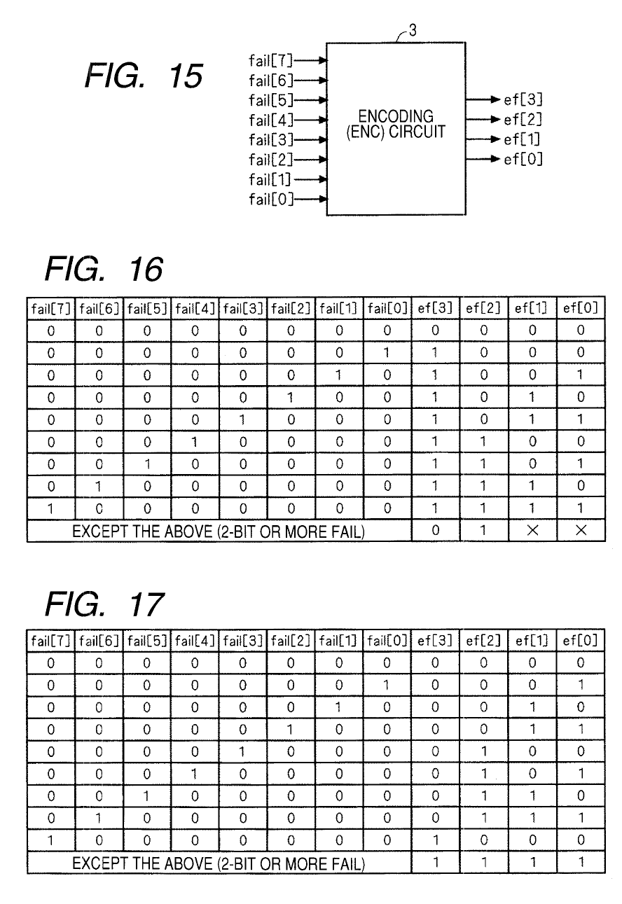

FIG. 15 is an explanatory diagram illustrating typically input/output relation of the encoding circuit 3 illustrated in FIG. 14. As illustrated in FIG. 15, the encoding circuit 3 receives and encodes the eight-bit failure bit data fail [0]-fail [7], and obtains the encoded data ef [0]-ef [3] compressed into four bits.

FIG. 16 is an explanatory diagram illustrating an example of a first encoding table by the encoding circuit 3 illustrated in FIG. 14. As illustrated in FIG. 16, when all the failure bit data fail [0]-fail [7] are “0”, all the encoded data ef [0]-ef [3] are set to “0”.

When “1” (failure bit) is detected in only one of the failure bit data fail [0]-fail [7], the encoded data ef [3] is set to “1.” The position (i) of the failure bit data fail [i] indicating “1” is expressed with the binary digit of the encoded data ef [0]-ef [2]. For example, in the case of the failure bit data fail [6]=1, it is set that ef [2]=1, ef [1]=1, and ef [0]=0, and that ef [2:0]=“110” (binary digit)=6 (decimal digit).

When “1” is detected in two or more of the failure bit data fail [0]-fail [7], it is set that the encoded data ef [3]=0 and the encoded data ef [2]=1. The values of the encoded data ef [1] and the encoded data ef [0] are arbitrary in this case.

FIG. 17 is an explanatory diagram illustrating an example of a second encoding table by the encoding circuit 3. As illustrated in FIG. 17, when all the failure bit data fail [0]-fail [7] are “0”, all the encoded data ef [0]-ef [3] are set to “0.”

When “1” (failure bit) is detected only in one of the failure bit data fail [0]-fail [7], the value (i+1) which is incremented by “1” to the position of the failure bit data fail [i] indicating “1” is expressed with the binary digit of the encoded data ef [0]-ef [3]. For example, in the case of the failure bit data fail [6]=1, it is set that ef [3]=0, ef [2]=1, ef [1]=1, and ef [0]=1, and that ef [3:0]=“0111” (binary digit)=7 (decimal digit).

When “1” is detected in two or more of the failure bit data fail [0]-fail [7], the encoded data ef [3:0] is set to “1111.”

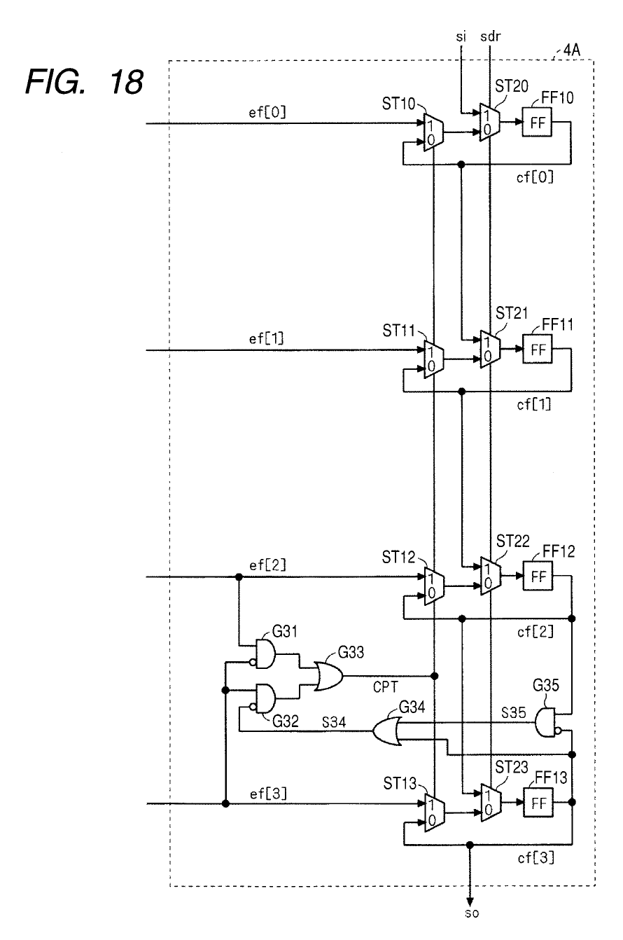

FIG. 18 is a circuit diagram illustrating the internal configuration of a capture circuit 4A of the first configuration of the capture circuit 4 corresponding to the encoding circuit 3 which performs encoding according to the example of the first encoding table illustrated in FIG. 16.

As illustrated in FIG. 18, the capture circuit 4A includes selectors ST10-ST13, selectors ST20-ST23, flip-flops FF10-FF13, AND gates G31, G32, and G35, and OR gates G33 and G34.

The selector ST10 receives the encoded data ef [0] at a “1” input. The selector ST20 receives a serial data input Si at a “1” input, the output of the selector ST10 at a “0” input, and a serial shift control signal sdr at a control input. The Flip-flop FF10 receives the output of the selector ST20 at an input terminal, and the latch data cf [0], which is the output of the Flip-flop FF10, is returned to a “0” input of the selector ST10.

The selector ST11 receives the encoded data ef [1] at a “1” input. The selector ST21 receives the latch data cf [0] of the flip-flop FF10 at a “1” input, the output of the selector ST11 at a “0” input, and the serial shift control signal sdr at a control input. The Flip-flop FF11 receives the output of the selector ST21 at an input terminal, and the latch data cf [1], which is the output of the Flip-flop FF11, is returned to a “0” input of the selector ST11.

The selector ST12 receives the encoded data ef [2] at a “1” input. The selector ST22 receives the latch data cf [1] of the flip-flop FF11 at a “1” input, the output of the selector ST12 at a “0” input, and the serial shift control signal sdr at a control input. The Flip-flop FF12 receives the output of the selector ST22 at an input terminal, and the latch data cf [2], which is the output of the Flip-flop FF12, is returned to a “0” input of the selector ST12.

The selector ST13 receives the encoded data ef [3] at a “1” input. The selector ST23 receives the latch data cf [2] of the flip-flop FF12 at a “1” input, the output of the selector ST13 at a “0” input, and the serial shift control signal sdr at a control input. The Flip-flop FF13 receives the output of the selector ST23 at an input terminal, and the latch data cf [3], which is the output of the Flip-flop FF13, is returned to a “0” input of the selector ST13 and at the same time the latch data cf [3] is outputted as a serial data output So.

The AND gate G31 receives the encoded data ef [2] at one input, and the inverted signal of the encoded data ef [3] at another input. The AND gate G32 receives the encoded data ef [3] at one input. The OR gate G33 receives the output of the AND gate G31 at one input, and the output of the AND gate G32 at another input. The output of the OR gate G33 is fed as a control input of the selectors ST10-ST13 as a capture signal CPT.

The AND gate G35 receives the latch data cf [2] at one input, and the inverted signal of the latch data cf [3] at another input. The OR gate G34 receives an AND gate output signal S35 of the AND gate G35 at one input, and the latch data cf [3] at another input. The inverted signal of the OR gate output signal S34 of the OR gate G34 is fed at another input of the AND gate G32.

The capture operation of the capture circuit 4A of configuration illustrated in FIG. 18 is explained. After initializing the flip-flops FF10-FF13 to “0”, the capture operation is practiced by setting the serial shift control signal sdr to “0.”

The initialization may be performed by setting that sdr=1 and si=0 and by supplying a clock to the flip-flops FF10-FF13 (initialization by a shift operation), or the initialization may be performed by employing a not-shown resetting means (for example, by employing flip-flops with a reset function in place of the flip-flops FF10-FF13). As a result of the initialization, the latch data cf [0]-cf [3] of the flip-flops FF10-FF13 are initialized to “10.”

First, a case where a failure bit is “0”, that is the case where the encoded data ef [3:0] is “0000” is explained.

In this case, since ef [2]=0, ef [3]=0, and both the outputs of the AND gates G31 and G32 become “0”, the capture signal CPT is stabilized in “0.” Consequently, since a loop by a selector ST1j, a selector ST2j, and FF1j (j=0-3) is formed, the latch data cf of the flip-flops FF10-FF13 [3:0] maintains the initial value “0000.”

Then, the operation when one-bit failure is detected first is explained. In this case, ef [3]=1. At this moment, the latch data cf [2] and cf [3] maintains “0” which is set at the time of initialization, therefore, the OR gate output signal S34 maintains “0.”

Consequently, both one input (the encoded data ef [3]) and another input (the inverted signal of the OR gate output signal S34) of the AND gate G32 are set to “1”, therefore, the output of the AND gate G32 is set to “1” and the capture signal CPT which is the output of the OR gate G33 is set to “1.”

As a result, the value of the newest encoded data ef [0]-ef [3] at the time of the encoded data ef [3]=1 is latched to the flip-flops FF10-FF13 as the latch data cf [0]-cf [3].

Due to the latch data cf [3] latched to the flip-flop FF13, the OR gate output signal S34 is set to “1” and the output of the AND gate G32 is set to “0.” As a result, the capture signal CPT which is the output of the OR gate G33 is returned to “0” again.

As a result, the loop circuit is formed again by the selector ST1j, the selector ST2j, and FF1j, and the value of the latch data cf [0]-cf [3] are maintained. Consequently, new encoded data ef [0]-ef [3] inputted after that are not latched as the latch data cf [0]-cf [3] of the flip-flops FF10-FF13.

After the encoded data ef [3]=1 is latched to the flip-flop FF13, the latch data cf [3] is set to “1”, and as described above, the OR gate output signal S34 of the OR gate G34 is fixed to “1.”

Consequently, even if the one-bit failure of the encoded data ef [3]=1 is detected after that, the encoded data ef [3:0] concerned is not taken into the flip-flops FF10-FF13, since another input of the AND gate G32 is “0” (the inverted signal of the OR gate output signal S34 of “1”).

Next, the case where failure of two bits or more is detected is explained. In this case, since the condition that ef [3]=0 and ef [2]=1 is satisfied, the output of the AND gate G31 is set to “1”, and the capture signal CPT which is the output of the OR gate G33 is set to “1.”

As a result, the encoded data ef [3]=0 and the encoded data ef [2]=1 are latched to the flip-flops FF12 and FF13.

Due to the latch data cf [3]=0 and the latch data cf [2]=1, the AND gate output signal S35 is set to “1”, and the OR gate output signal S34 is set to “1.” Consequently, the output of the AND gate G32 is set to “0”, and, as a result, the capture signal CPT which is the output of the OR gate G33 is returned to “0” again.

As a result, the loop circuit by the selector ST1j, the selector ST2j, and FF1j is formed again, and the value of the latch data cf [0]-cf [3] is maintained. Consequently, new encoded data ef [0]-ef [3] inputted after that are not latched as the latch data cf [0]-cf [3] of the flip-flops FF10-FF13.

After the encoded data ef [3]=0 is latched to the flip-flop FF13 and the encoded data ef [2]=1 is latched to the flip-flop FF12, the OR gate output signal S34 of the OR gate G34 is fixed to “1”, as described above. Consequently, even if the one-bit failure of the encoded data ef [3]=1 is detected after that, the encoded data ef [3]=1 is not taken into the flip-flops FF10-FF13.

In this way, the capture circuit 4A latches all “0” as the latch data cf [0]-cf [3], when there is no failure. When one-bit failure is detected, the latch data cf [3]=1 and the latch data cf [0]-cf [2] which indicate the failure position of the one-bit failure detected first are latched. When two-bit or more failure is detected, the encoded data ef [3]=1 and the encoded data ef [2]=1 are latched.

After the end of the capture operation, the capture circuit 4A can output serially the encoded data ef [0]-ef [3] latched to the flip-flops FF10-FF13 as the serial data output So, by setting the serial shift control signal sdr to “1.”

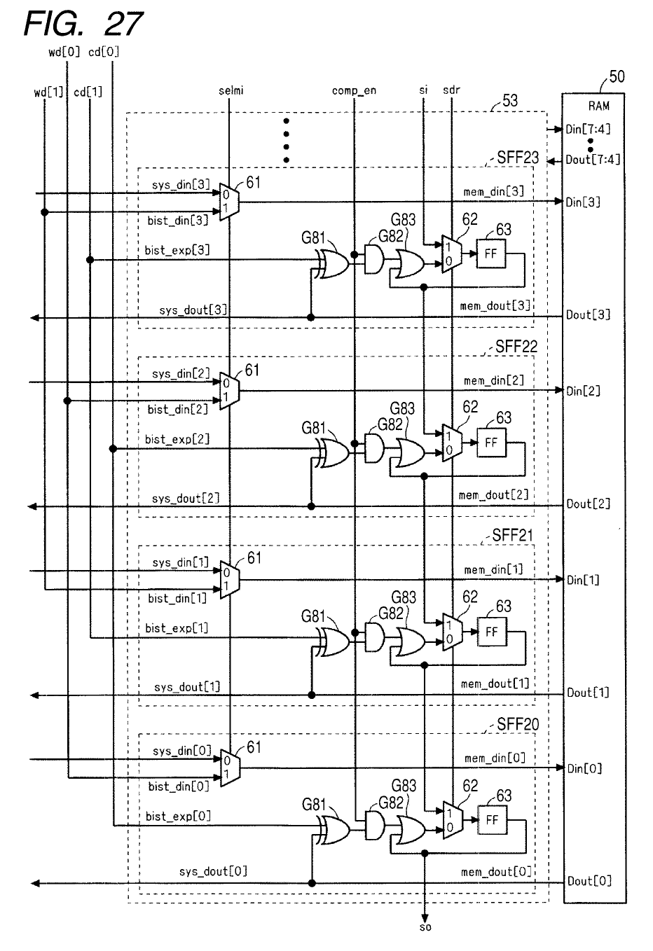

In this way, the failure information can be read out as the serial data output So by the serial shift operation of the capture circuit 4A. Namely, this fact means that the result equivalent to the sequential encoder circuit of Document 1 is obtained as the serial data output So. Compared with the configuration illustrated in FIG. 27, the semiconductor integrated circuit of Embodiment 5 can promote improvement in the degree of integration by decreasing the number of flip-flops (decrease from 8 to 4).

As described above, the capture circuit 4A in the semiconductor integrated circuit of Embodiment 5 can be composed by providing only the latch circuit (flip-flops FF10-FF13) of four bits which is the number of compressed bits smaller than eight bits which is the number of data input/output bits. The latch data cf [3:0] can indicate the first failure information on the nonexistence of failure bit, and the second failure information on the existence of one-bit failure and the bit location.

Consequently, the semiconductor integrated circuit of Embodiment 5 has the configuration in which the four-bit latch circuit is provided to treat the data input/output of eight bits. Therefore, the semiconductor integrated circuit of Embodiment 5 can produce the effect that the degree of integration is improved as much, and the failure repair to RAM 1 using a redundancy memory is achievable, based on the latch data cf [3:0].

Furthermore, the semiconductor integrated circuit of Embodiment 5 can recognize that failure of two bits or more exists in the data input/output of RAM 1 by the latch data cf [3:0] (the encoded data ef [3:0]), therefore, a higher-precision failure analysis can be performed.

In addition, the capture circuit 4A of the semiconductor integrated circuit of Embodiment 5 outputs the latch data cf [3:0] serially from the serial data output So, allowing external recognition of the contents of latch data cf [3:0] as serial data.

The latch condition of the capture circuit 4A of the semiconductor integrated circuit of Embodiment 5 has a condition that the first-detected second failure information on the failure position of one-bit failure is latched more preferentially than the first failure information on the nonexistence of failure. Therefore, when the existence of failure of one bit in the data input/output of RAM 1 is recognized, failure recovery can be certainly practiced on the input/output of the first-detected failure bit.

Furthermore, the latch condition of the capture circuit 4A of the semiconductor integrated circuit of Embodiment 5 has another condition that the third failure information on failure of two or more bits is latched more preferentially than the first and the second failure information. Therefore, the information on two-bit failure of the data input/output which is unrepairable in general can be obtained preferentially, thereby producing the effect that efficient failure recovery can be performed, avoiding the failure repair of the memory circuit in which the failure recovery is difficult.

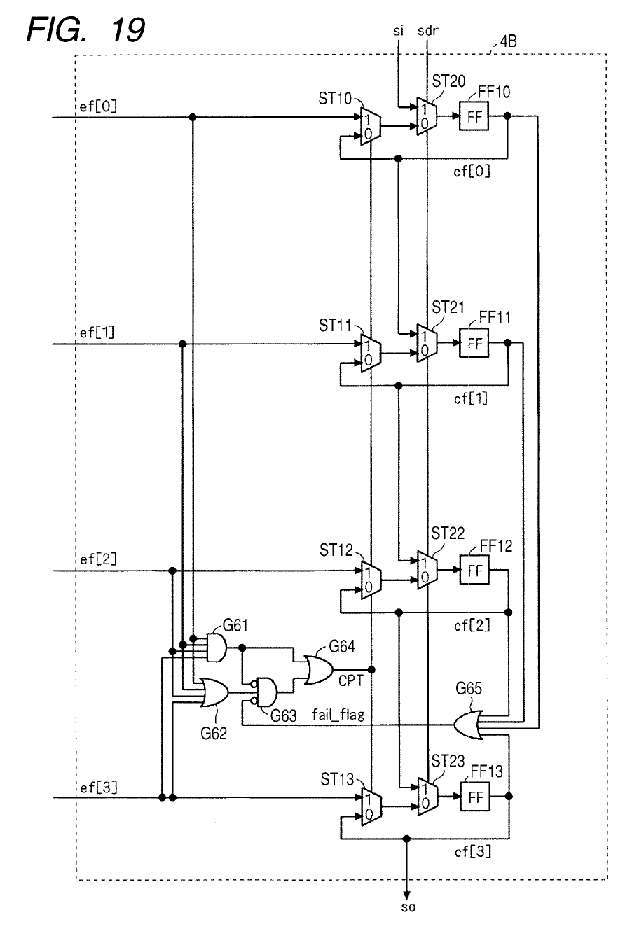

FIG. 19 is a circuit diagram illustrating the internal configuration of a capture circuit 4B of the second configuration of the capture circuit 4, corresponding to the encoding circuit 3 which performs encoding according to the example of the second encoding table illustrated in FIG. 17.

As illustrated in FIG. 19, the capture circuit 4B includes selectors ST10-ST13, selectors ST20-ST23, flip-flops FF10-FF13, AND gates G61 and G63, and OR gates G62, G64 and G65.

Since the loop arrangement by the selectors ST10-ST13, the selectors ST20-ST23, and the flip-flops FF10-FF13 is the same as that of the capture circuit 4A illustrated in FIG. 18, the explanation thereof is omitted.

The 4-input AND gate G61 receives the encoded data ef [0]-ef [3] at a first to a fourth input. The 4-input OR gate G62 receives the encoded data ef [0]-ef [3] at a first to a fourth input. The 3-input AND gate G63 receives the inverted output signal of the AND gate G61 at a first input, and receives the output signal of the OR gate G62 at a second input.

The OR gate G64 receives the output signal of the AND gate G61 at one input, and receives the output signal of the AND gate G63 at another input. The output signal of the OR gate G64 is fed to the control input of the selectors ST10-ST13 as a capture signal CPT.

The 4-input OR gate G65 receives the latch data cf [0]-cf [3] at a first to a fourth input, and the output signal of the OR gate G65 serves as the fail flag fail_flag and is fed to a third input of the AND gate G63.

The capture operation of the capture circuit 4B of configuration illustrated in FIG. 19 is explained. As in the capture circuit 4A, after initializing the flip-flops FF10-FF13 to “0”, the capture operation is practiced by setting the serial shift control signal sdr to “0.”

First, a case where a failure bit is “0”, that is the case where the encoded data ef [3:0] is “0000” is explained.

In this case, the encoded data ef [3:0]=“0000”, the output of the AND gate G61 is set to “0”, the output of the OR gate G62 is set to “0”, and the output of the AND gate G63 is set to “0.” Therefore, the capture signal CPT which is the output of the OR gate G64 is stabilized in “0.”

Consequently, since a loop by a selector ST1j, a selector ST2j, and FF1j (j=0-3) is formed, the latch data cf of the flip-flops FF10-FF13 [3:0] maintains the initial value “0000.”

Then, the operation when one-bit failure is detected first is explained. In this case, the encoded data ef [3:0] is not “1111”, and at least one of the encoded data ef [0]-ef [3] is set to “1.” Hereafter, the encoded data ef [3:0] in the present case is called the encoded data ef [3:0] in one-bit failure detection.

Since, at this moment, all the latch data cf [0]-cf [3] maintain “0” which are set at the time of initialization, the fail flag fail_flag which is the output of the OR gate G65 maintains “0.”

Consequently, the output of the AND gate G61 is set to “0” (the inverted signal is “1”), the output of the OR gate G62 is set to “1”, and the fail flag fail_flag is set to “0” (the inverted signal is “1”). Therefore, the output of the AND gate G63 is set to “1”, and the capture signal CPT which is the output of the OR gate G64 is set to “1.”

As a result, the value of the newest encoded data ef [0]-ef [3] are latched to the flip-flops FF10-FF13.

At least one of the encoded data ef [0]-ef [3] is set to “1”, the fail flag fail_flag is set to “1”, and the output of the AND gate G63 returns to “0.” As a result, the capture signal CPT which is the output of the OR gate G64 returns to “0” again.

Then, the latched latch data cf [0]-cf [3] are maintained by the loop circuit by the selector ST1j, the selector ST2j, and FF1j.

The encoded data ef [0]-ef [3], of which the encoded data ef [3:0] is not “1111” and at least one of the encoded data ef [0]-ef [3] is set to “1”, are latched to the flip-flops FF10-FF13. As a result, as described above, the fail flag fail_flag which is the output of the OR gate G65 is fixed to “1.” Consequently, even if the encoded data ef [3:0] in one-bit failure detection is inputted after that, the output of the AND gate G63 is not set to “1”, the capture signal CPT maintains “0”, and hence the encoded data ef [3:0] is not taken into the flip-flops FF10-FF13.

Next, the case where failure of two bits or more is detected is explained. In this case, the condition that the encoded data ef [3:0]=“1111” is satisfied; therefore, the output of the AND gate G61 is set to “1”, and the capture signal CPT which is the output of the OR gate G64 is set to “1.”

As a result, the encoded data ef [3:0]=“1111” is latched to the flip-flops FF10-FF13.

All the encoded data ef [0]-ef(s) [3] are set to “1”, the fail flag fail_flag is set to “1”, and the output of the AND gate G63 returns to “0.” As a result, at the time of the input of new encoded data ef [3:0], the capture signal CPT which is the output of the OR gate G64 returns to “0” again.

The encoded data ef [3:0]=“1111” is latched to the flip-flops FF10-FF13. Consequently, the fail flag fail_flag which is the output of the OR gate G65 as described above is fixed to “1.” Consequently, even if the encoded data ef [3:0] in one-bit failure detection is inputted after that, the encoded data ef [3:0] is not taken into the flip-flops FF10-FF13.

In this way, the capture circuit 4B, which is the second example of configuration, latches all “0” as the latch data cf [0]-cf [3], when there is no failure. When one-bit failure is detected, the latch data cf [0]-cf [3] indicating “failure position+1” of the one-bit failure detected first are latched. When failure of two bits or more is detected, the encoded data ef [3:0]=“1111” is latched.

After the end of the capture operation, the capture circuit 4B can output serially the encoded data ef [0]-ef [3] latched to the flip-flops FF10-FF13 as the serial data output So, by setting the serial shift control signal sdr to “1.”

In this way, by employing the capture circuit 4B, the same effect as in the case where the capture circuit 4A is employed can be obtained also.

### Embodiment 6

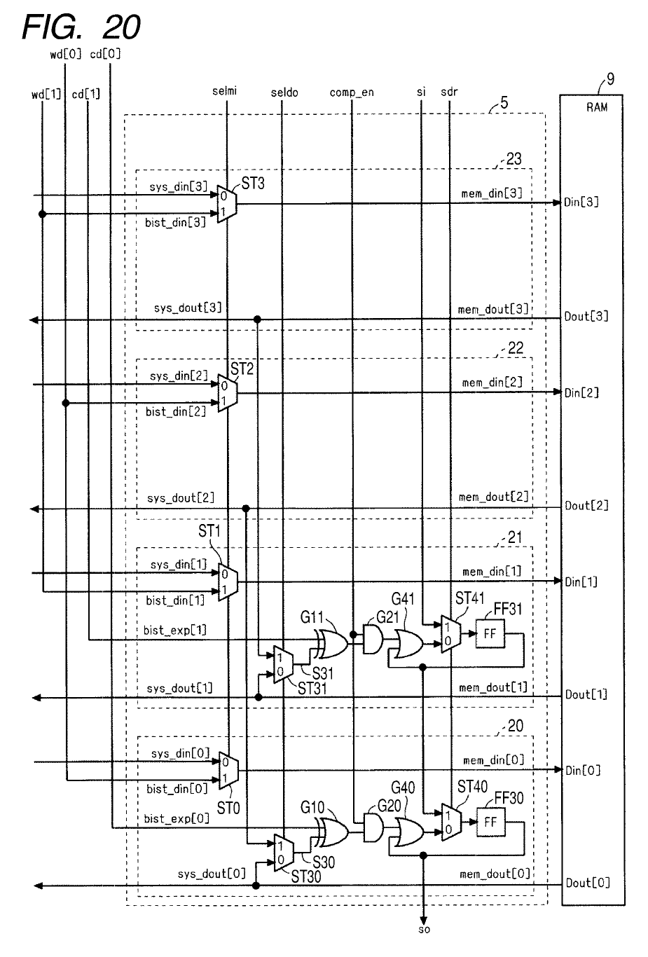

FIG. 20 is a circuit diagram illustrating a first illustrative embodiment of a semiconductor integrated circuit having a failure analysis function, according to Embodiment 6 of the present invention. As illustrated in FIG. 20, RAM 9 has a four-bit (the predetermined number of bits) data input/output function (function corresponding to data inputs Din [0]-Din [3 ] and data outputs Dout [0]-Dout [3]).

A data input/output controller 5 is provided to control the data inputs Din [0]-Din [3 ] and the data outputs Dout [0]-Dout [3] of RAM 9.

As illustrated in FIG. 20, a one-bit input/output controller 20 includes selectors ST30 and ST40, an OR gate G40, and a flip-flop FF30, in addition to a selector ST0, an EXOR gate G10, and an AND gate G20.

The selector ST0 receives write-in data sys_din [0] at a “0” input, write-in data bist_din [0] at a “1” input, and a mode selector control signal selmi at a control input. The output of the selector ST0 is fed to the data input Din [0] of RAM 9 as RAM input data mem_din [0].

The selector ST30 receives the data output Dout [2] at a “1” input, the data output Dout [0] at a “0” input, and the data output selection signal seldo at a control input. The EXOR gate G10 receives write-in data bist_exp [0] at one input, and the output of the selector ST30 at another input. The AND gate G20 receives a comparison enable signal comp_en at one input, and receives the output of the EXOR gate G10 at another input.

The OR gate G40 receives the output of the AND gate G20 at one input. The selector ST40 receives the output of the flip-flop FF31 of the one-bit input/output controller 21 at a “1” input, the output of the OR gate G40 at a “0” input, and a serial shift control signal sdr at a control input.

The flip-flop FF30 receives the output of the selector ST40 at an input terminal, and the output of the flip-flop FF30 is returned to another input of the OR gate G40. The output of the flip-flop FF30 is outputted as the serial data output So. The data output Dout [0] is outputted as the write-in data sys_din [0].

The one-bit input/output controller 21 includes selectors ST31 and ST41, an OR gate G41, and a flip-flop FF31 in addition to a selector ST1, an EXOR gate G11, and an AND gate G21.

The selector ST1 receives write-in data sys_din [1] at a “0” input, write-in data bist_din [1] at a “1” input, and a mode selector control signal selmi at a control input. The output of the selector ST1 is fed to the data input Din [1] of RAM 9 as RAM input data mem_din [1].

The selector ST31 receives the data output Dout [3] at a “1” input, the data output Dout [1] at a “0” input, and the data output selection signal seldo at a control input. The EXOR gate G11 receives write-in data bist_exp [1] at one input, and the output of the selector ST31 at another input. The AND gate G21 receives a comparison enable signal comp_en at one input, and receives the output of the EXOR gate G11 at another input.

The OR gate G41 receives the output of the AND gate G21 at one input. The selector ST41 receives a serial data input Si at a “1” input, the output of the OR gate G41 at a “0” input, and a serial shift control signal sdr at a control input.

The flip-flop FF31 receives the output of the selector ST41 at an input terminal, and the output of the flip-flop FF31 is returned to another input of the OR gate G41. The output of the flip-flop FF31 is also fed to a “1” input of the selector ST40 of the one-bit input/output controller 20 as described above. The data output Dout [1] is outputted as the write-in data sys_din [1].

On the other hand, the one-bit input/output controller 22 includes only a selector ST2. The selector ST2 receives write-in data sys_din [2] at a “0” input, write-in data bist_din [2] at a “1” input, and a mode selector control signal selmi at a control input. The output of the selector ST2 is fed to the data input Din [2] of RAM 9 as RAM input data mem_din [2].

As described above, the data output Dout [2] is outputted as write-in data sys_din [2], and also fed to a “1” input of the selector ST30 of the one-bit input/output controller 20.

Similarly, the one-bit input/output controller 23 includes only a selector ST3. The selector ST3 receives write-in data sys_din [3] at a “0” input, write-in data bist_din [3] at a “1” input, and a mode selector control signal selmi at a control input. The output of the selector ST3 is fed to the data input Din [3] of RAM 9 as RAM input data mem_din [3].

As described above, the data output Dout [3] is outputted as write-in data sys_din [3], and also fed to a “1” input of the selector ST31 of the one-bit input/output controller 21.

In such configuration, the data output to be compared with the write-in data bist_exp [0] can be switched to the data output Dout [0] or the data output Dout [2] by the data output selection signal seldo, and the switched data output is inputted into a comparison circuit (the EXOR gate G10 and the AND gate G20), thereby allowing the flip-flop FF30 to latch the comparison result.

Similarly, the data output to be compared with the write-in data bist_exp [1] can be switched to the data output Dout [1] or the data output Dout [3] by the data output selection signal seldo, and the switched data output is inputted into a comparison circuit (the EXOR gate G11 and the AND gate G21), thereby allowing the flip-flop FF31 to latch the comparison result.

As in the semiconductor integrated circuit of Embodiment 5, in the semiconductor integrated circuit of Embodiment 6, the test write data (wd [0], wd [1]) and the test expectation value (cd [0], cd [1] are grouped into two of the input/output bits of even numbers and odd numbers, in order to reduce the number of signal wiring.

In this way, by changing the data output selection signal seldo suitably at the time of the test, and making all the data outputs Dout [0]-Dout [3] of RAM 9 accessible, the comparison result to the four-bit data output Dout [0]-Dout [3] can be latched by two flip-flops FF30 and FF31.

The data input/output controller 5 of the semiconductor integrated circuit of the first illustrative embodiment of Embodiment 6 is an effective circuit when failure position information is unnecessary (for example, in cases where the IO repair is not applied to RAM 9).

However, in the first illustrative embodiment, it can be recognized whether the failure bit has occurred at odd bits or at even bits, by identifying whether the latch data is of the flip-flop FF30 or of the flip-flop FF31.

In this way, in the first illustrative embodiment of the semiconductor integrated circuit of Embodiment 6, the comparison result of the comparison circuit (G10, G20 or G11, G21), which is provided to two pieces of the data output Dout [i] in a one-to-two pieces manner, is stored in one flip-flop (FF30 or FF31). Therefore, compared with the case where the data input/output of configuration illustrated as the related art in FIG. 27 is assumed to be a four-bit configuration, the semiconductor integrated circuit in the first illustrative embodiment can be composed of the flip-flops of the fewer number “2” than the number “4” of the data input/output bits. Therefore, it is possible to produce the effect that the failure analysis to RAM 9 can be conducted, promoting improvement in the degree of integration at the same time.

In the data input/output controller 5 illustrated in FIG. 20, two-bit data output Dout [i] is selected using the 2-input selectors ST30 and ST31. However, further improvement in the degree of integration can be promoted, by selecting the data output Dout [i] of three bits or more with the use of a 3-or-more input selector according to the number of I/O bits of RAM.

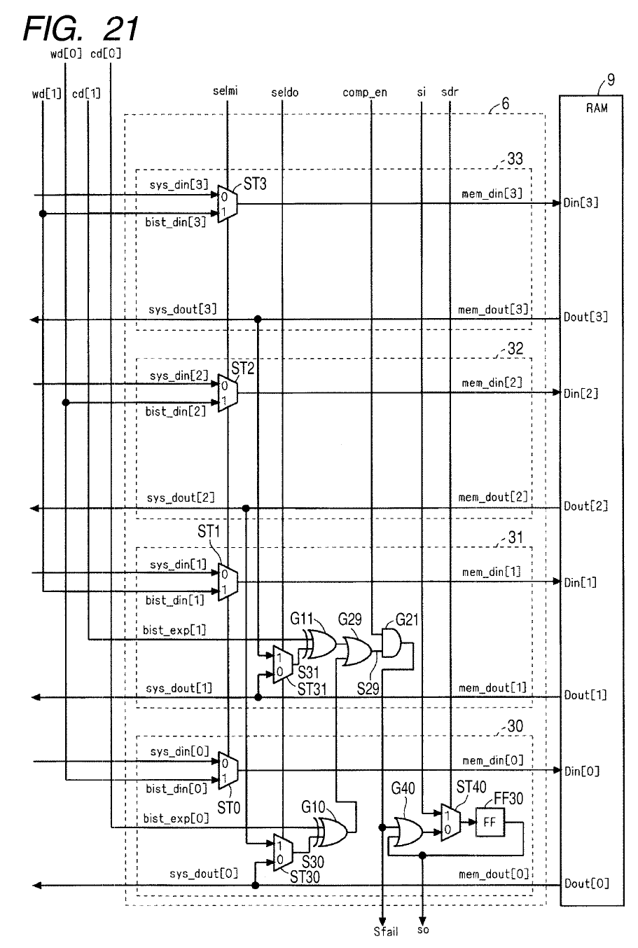

FIG. 21 is a circuit diagram illustrating a second illustrative embodiment of a semiconductor integrated circuit having a failure analysis function, according to Embodiment 6 of the present invention. As illustrated in FIG. 21, a data input/output controller 6 is provided to RAM 9.

As illustrated in FIG. 21, a one-bit input/output controller 30 includes selectors ST30 and ST40, an OR gate G40, and a flip-flop FF30 in addition to a selector ST0, an EXOR gate G10, and an AND gate G20.

The selector ST0 receives write-in data sys_din [0] at a “0” input, write-in data bist_din [0] at a “1” input, and a mode selector control signal selmi at a control input. The output of the selector ST0 is fed to the data input Din [0] of RAM 9 as RAM input data mem_din [0].

The selector ST30 receives the data output Dout [2] at a “1” input, the data output Dout [0] at a “0” input, and the data output selection signal seldo at a control input. The EXOR gate G10 receives write-in data bist_exp [0] at one input, and the output of the selector ST30 at another input.

The OR gate G40 receives a failure signal Sfail from a one-bit input/output controller 31 at one input. The selector ST40 receives a serial data input Si at a “1” input, the output of the OR gate G40 at a “0” input, and a serial shift control signal sdr at a control input.

The flip-flop FF30 receives the output of the selector ST40 at an input terminal, and the output of the flip-flop FF30 is returned to another input of the OR gate G40. The output of the flip-flop FF30 is outputted as the serial data output So. The data output Dout [0] is outputted as the write-in data sys_din [0].

The one-bit input/output controller 31 includes a selector ST31 and an OR gate 29, in addition to a selector ST1, an EXOR gate G11, and an AND gate G21.

The selector ST1 receives write-in data sys_din [1] at a “0” input, write-in data bist_din [1] at a “1” input, and the mode selector control signal selmi at a control input. The output of the selector ST1 is fed to the data input Din [1] of RAM 9 as RAM input data mem_din [1].

The selector ST31 receives the data output Dout [3] at a “1” input, the data output Dout [1] at a “0” input, and the data output selection signal seldo at a control input. The EXOR gate G11 receives write-in data bist_exp [1] at one input, and the output of the selector ST31 at another input.

The OR gate G29 receives the output of the EXOR gate G11 at one input, and the output of the EXOR gate G10 of the one-bit input/output controller 30 at another input.

The AND gate G21 receives a comparison enable signal comp_en at one input, and receives the output of the EXOR gate G29 at another input. The output of the AND gate G21 is fed as the failure signal Sfail at one input of the OR gate G40 of the one-bit input/output controller 30, as described above.

On the other hand, the one-bit input/output controller 32 includes only a selector ST2, and has the configuration as in the one-bit input/output controller 22 of the first illustrative embodiment. The one-bit input/output controller 33 includes only a selector ST3, and has the configuration as in the one-bit input/output controller 23 of the first illustrative embodiment.

In such configuration, the data output to be compared with the write-in data bist_exp [0] can be switched to the data output Dout [0] or the data output Dout [2] by the data output selection signal seldo, and the switched data output is fed to the comparison circuit (the EXOR gate G10 and the OR gate G29), thereby allowing the flip-flop FF30 to latch the comparison result.

Similarly, the data output to be compared with the write-in data bist_exp [1] can be switched to the data output Dout [1] or the data output Dout [3] by the data output selection signal seldo, and the switched data output is fed to the comparison circuit (the EXOR gate G11 and the OR gate G29), thereby allowing the flip-flop FF30 to latch the comparison result.

In this way, in the second illustrative embodiment, by changing the data output selection signal seldo suitably at the time of the test, and making all the data outputs Dout [0]-Dout [3] of RAM 9 accessible, the comparison result to the four-bit data output Dout [0]-Dout [3] can be obtained as two comparison results (the output of the EXOR gates G10 and G11).

Furthermore, in the second illustrative embodiment of the semiconductor integrated circuit of Embodiment 6, the latch unit (the flip-flop FF30) is provided to latch the failure signal Sfail which is a comprehensive comparison result obtained by determining whether at least one comparison result between the two comparison results described above denotes the existence of a failure bit.

As a result, the configuration which provides one flip-flop FF30 latching the failure signal Sfail to two comparison results is realized. Therefore, it is possible to produce the effect that the second illustrative embodiment of Embodiment 6 improves as much the degree of integration more than the first illustrative embodiment, and can conduct the failure analysis to RAM 9.

In this way, in the second illustrative embodiment of the semiconductor integrated circuit of Embodiment 6, by combining with the effect of the first illustrative embodiment and storing in one flip-flop the comparison result to the four-bit data output Dout [i], the degree of integration can be further promoted by decreasing the number of flip-flops (the decrease from “4” to “1”), in comparison with the configuration illustrated in FIG. 27.

However, in the second illustrative embodiment, it cannot be recognized whether the failure bit occurred at odd bits, or at even bits, in contrast to the first illustrative embodiment.

Similarly to the first illustrative embodiment, the data input/output controller 6 of the semiconductor integrated circuit of the second illustrative embodiment of Embodiment 6 is an effective circuit, when the failure position information is unnecessary.

In the data input/output controller 6 illustrated in FIG. 21, the data output Dout [i] is selected using the 2-input selectors ST30 and ST31. However, a 3-or-more-input selector can also be employed according to the number of I/O bits of RAM.

### Embodiment 7

### (Principle of an Invention)

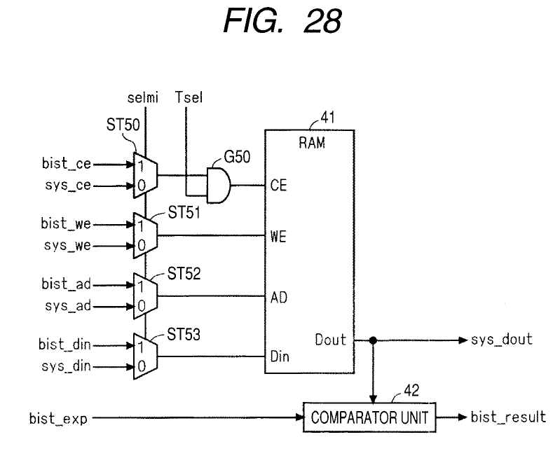

FIG. 28 is an explanatory diagram illustrating the configuration of a semiconductor integrated circuit having a failure analysis function in the related art. As illustrated in FIG. 28, RAM 41 has a chip enable input CE, a write enable input WE, an address input AD [*], a data input Din [*], and a data output Dout.

A comparator unit 42, selectors ST50-ST53, and an AND gate G50 are provided in order to enable the test of the existence or nonexistence of a failure bit to RAM 41.

The comparator unit 42 compares a data output Dout with a write-in expectation value bist_ext, and outputs a comparison result signal bist_result which indicates the existence or nonexistence of a failure bit.

The selector ST50 receives a chip enable signal bist_ce at a “1” input, receives a chip enable signal sys_ce at a “0” input, and receives a mode selector control signal selmi at a control input.

The AND gate G50 receives the output of the selector ST50 at one input, and receives a test selection signal Tsel at another input. The test selection signal Tsel is set to “1” to a selection-target RAM at the time of a test, and is set to “0” to a non-selection-target RAM at the time of a test. The output of the AND gate G50 is fed to the chip enable input CE of RAM 41.

The selector ST51 receives a write enable signal bist_we at a “1” input, receives a write enable signal sys_we at a “0” input, and receives the mode selector control signal selmi at a control input. The output of the selector ST51 is fed to the write enable input WE of RAM 41.

The selector ST52 receives an address signal bist_ad [*] at a “1” input, receives an address signal sys_ad [*] at a “0” input, and receives the mode selector control signal selmi at a control input. The output of the selector ST52 is fed to the address input AD [*] of RAM 41.

The selector ST53 receives address signal write data bist_din [*] at a “1” input, receives write-in data sys_din [*] at a “0” input, and receives the mode selector control signal selmi at a control input. The output of the selector ST53 is fed to the data input Din [*] of RAM 41.

The chip enable signal bist_ce, the write enable signal bist_we, the address signal bist_ad [*], and the write-in data bist_din [*] are employed at the time of a test. On the other hand, the chip enable signal sys_ce, the write enable signal sys_we, the address signal sys_ad [*], and the write-in data sys_din [*] are employed at the time of normal operation.

In such configuration, when the test selection signal Tsel is “0” and RAM 41 is not a test target, the output of the AND gate G50 is set to “0”, and the chip enable input CE of RAM 41 is compulsorily set to “0” to control RAM 41 to be inactive. As a result, decreasing the power consumption of RAM 41 at the time of a test to be carried out when RAM 41 is not a test target.

However, the write enable signal bist_we, the address signal bist_ad [*], and the write-in data bist_din [*] have been inputted as the write enable signal WE, the address signal AD and the data input signal Din of RAM 41.

Consequently, when the write enable signal WE, the address signal AD, and the data input signal Din of RAM 41 change, a signal buffer, etc. inside RAM 41 operates at the time of a test even when RAM 41 is not a test target, thereby causing a problem that the power is consumed.

For example, assuming that there exist 100 pieces of RAMs equivalent to RAM 41 and that ten pieces of RAMs undergo a test, and even when the chip enable input CE of the remaining 90 pieces of RAMs as non-test-targets is controlled to “0”, a small amount of power is consumed in each of 90 pieces of RAMs, resulting in a large amount of power consumption as a whole. This unnecessary power consumption causes the line voltage variation, etc. at the time of a test, thereby causing a problem of creating an unfavorable factor which disturbs a highly precise test. Embodiment 7 is accomplished in order to solve the problem.

### Configuration of Embodiment 7

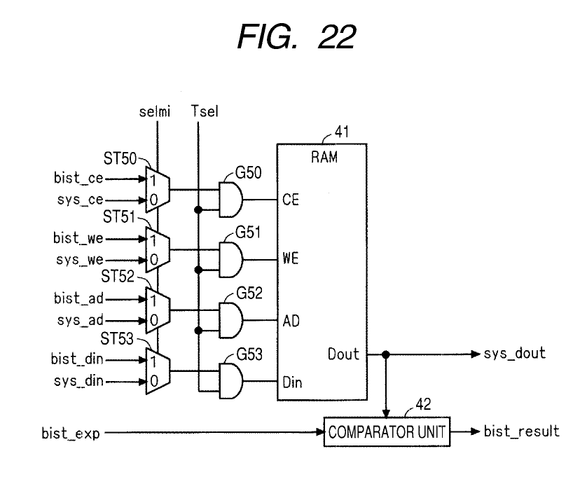

FIG. 22 is an explanatory diagram illustrating the configuration of a semiconductor integrated circuit having a failure analysis function, according to Embodiment 7 of the present invention. As illustrated in FIG. 22, RAM 41 has a chip enable input CE, a write enable input WE, an address input AD [*], a data input Din [*], and a data output Dout.

A comparator unit 42, selectors ST50-ST53, and AND gates G50-G53 are provided in order to enable the test of the existence or nonexistence of a failure bit to RAM 41. The following explains the present configuration centering on a different point from the configuration illustrated in FIG. 28.

The selector ST51 receives a write enable signal bist_we at a “1” input, receives a write enable signal sys_we at a “0” input, and receives a mode selector control signal selmi at a control input.

The AND gate G51 receives the output of the selector ST51 at one input, and receives a test selection signal Tsel at another input. The output of the AND gate G51 is fed to the write enable input WE of RAM 41.

The selector ST52 receives an address signal bist_ad [*] at a “1” input, receives an address signal sys_ad [*] at a “0” input, and receives the mode selector control signal selmi at a control input.

The AND gate G52 receives the output of the selector ST52 at one input, and receives the test selection signal Tsel at another input. The output of the AND gate G52 is fed to the address input AD [*] of RAM 41.

The selector ST53 receives address signal write data bist_din [*] at a “1” input, receives write-in data sys_din [*] at a “0” input, and receives the mode selector control signal selmi at a control input.

The AND gate G53 receives the output of the selector ST53 at one input, and receives the test selection signal Tsel at another input. The output of the AND gate G53 is fed to the data input Din [*] of RAM 41. The other configuration is the same as the configuration illustrated in FIG. 28.

Consequently, when the test selection signal Tsel is “0” which denotes a non-test target, the AND gates G50-G53 function as a non-test-target disenabling means which nullifies the chip enable input CE, the write enable input WE, the address input AD [*], and the data input Din [*] to “0.”

In such configuration, when RAM 41 is set to be not a test target by setting the test selection signal Tsel to “0”, the semiconductor integrated circuit of Embodiment 7 decreases the power consumption at the time of a test by setting the chip enable input CE of RAM 41 to “0”, to control RAM 41 to be inactive.

The semiconductor integrated circuit of Embodiment 7 also sets the output of the AND gates G51-G53 to “0”, sets compulsorily the write enable input WE, the address input AD [*], and the data input Din [*] of RAM 41 to “0”, thereby fixing these inputs as well.

As a result, the increase of power consumption resulting from the voltage change of the write enable input WE, the address input AD [*], and the data input Din [*] of RAM 41 may be completely avoided. As a result, the semiconductor integrated circuit of Embodiment 7 produces the effect that higher-precision failure detection can be carried out, by fully eliminating the factor which disturbs a highly precise test, such that, when RAM is not a test target, the RAM does not induce line voltage variation, etc. at the time of a test.

Although the write enable input WE(s), the address inputs AD [*], and the data inputs Din [*] have been all fixed to produce the effect in Embodiment 7, the same effect can be obtained by inserting a gate circuit partially. For example, even if the configuration is employed in which only the data input Din [*] is fixed at the time when the test selection signal Tsel is “0”, it is possible to produce the effect that otherwise adverse influence on the fixed signal can be certainly avoided.

In FIG. 22, the AND gates G50-G53 are inserted in the part of the input terminal of RAM 41. However, the AND gates G50-G53 may be inserted in the BIST signal input side (bist_ce, bist_we, bist_ad, bist_din) of the selectors ST50-ST53. In this case, there is an advantage that it is not necessary to set the test selection signal Tsel to “1” at the time of the normal operation of the semiconductor integrated circuit.

Although the example of one piece of RAM 41 is illustrated in FIG. 22, it is also expected to employ a semiconductor integrated circuit including plural RAMs which carry out the input control of the chip enable input CE, the write enable input WE, the address input AD [*], and the data input Din [*], as in RAM 41. That is, it is possible to compose the semiconductor integrated circuit which includes plural RAMs equivalent to RAM 41 and plural means, each equivalent to the non-test-target disenabling means, provided to the plural RAMs (however, the test selection signal Tsel is respectively provided independently). The above-described plural means, each equivalent to the non-test-target disenabling means, can be bundled to form a piece of the non-test-target disenabling means.

To the semiconductor integrated circuit of such configuration, when testing sequentially for every group of parts of the plural RAMs, the following processing are possible. In this case, to a non-test-target RAM among the plural RAMs, the chip enable input CE can be set to “0” and at least one of the write enable input WE, the address input AD [*], and the data inputs Din [*] can be nullified to “0”, by one of the plural non-test-target disenabling means (a means equivalent to the non-test-target disenabling means, corresponding to the non-test-target RAM).

### Embodiment 8

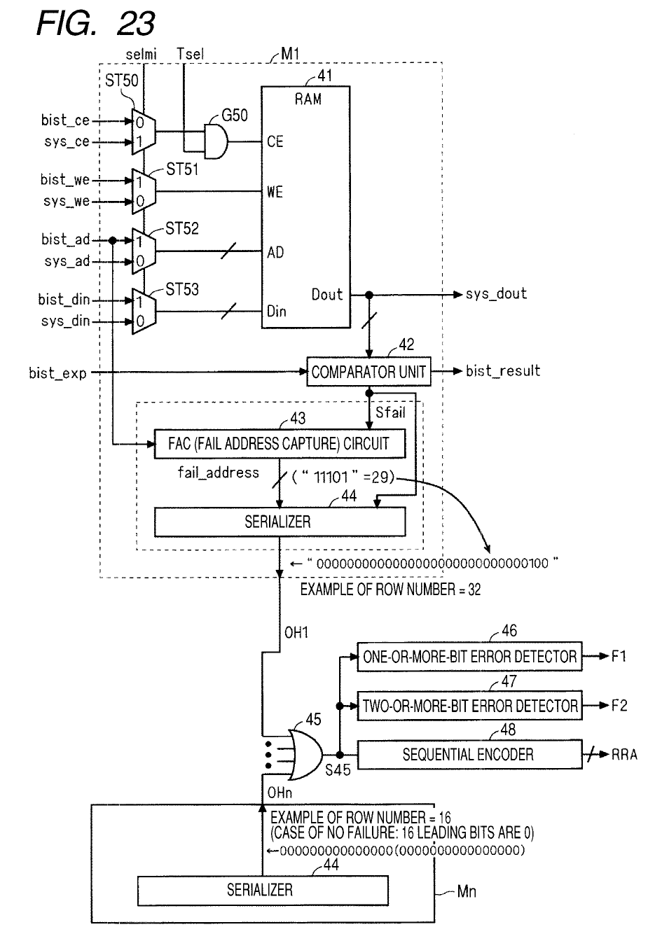

FIG. 23 is an explanatory diagram illustrating the configuration of a semiconductor integrated circuit having a failure analysis function, according to Embodiment 8 of the present invention.

As illustrated in FIG. 23, one unit including an OR gate 45, a one-or-more-bit error detector 46, a two-or-more-bit error detector 47, and a sequential encoder 48 is provided to n pieces of repair analysis circuit-attached RAM units M1-Mn.

The repair analysis circuit-attached RAM unit M1 includes RAM 41, selectors ST50-ST53, a AND gate G50, a comparator unit 42, an FAC circuit 43, and a serializer 44. In FIG. 23, the details of internal configuration are shown only for the repair analysis circuit-attached RAM unit M1, for the sake of explanation.

Although not shown, RAM 41 has a redundancy memory which is replaceable in row address units.

The FAC (Fail Address Capture) circuit 43 receives a failure signal Sfail which indicates the existence or nonexistence of failure occurrence from the comparator unit 42, and recognizes an address signal bist_ad [*] when the failure signal Sfail outputs “1.” Then, the FAC circuit 43 outputs, as a fail address fail_address, the address which denotes a row address among the address signal bist_ad [*] recognized when the failure signal Sfail is “1.”

The serializer 44 receives the failure signal Sfail and the fail address fail_address. When the failure signal Sfail outputs “1” (failure exists) even once, the serializer 44 outputs 32-bit One-Hot data OH1 (failure serial information) which is obtained on the basis of the fail address fail_address. The One-Hot data OH1 is a bit group of a 32-bit configuration of which only the bit of the position denoting the fail address fail_address is converted into “1”, and other bits are set to “0.”

Since the other configuration of the repair analysis circuit-attached RAM unit M1 is the same as the configuration illustrated in FIG. 28, the explanation thereof is omitted.

The repair analysis circuit-attached RAM unit Mn also has the same configuration as that of the repair analysis circuit-attached RAM unit M1, and outputs 32-bit One-Hot data OHn from the serializer 44. Although the number of valid bits of the actual One-Hot data of the repair analysis circuit-attached RAM unit Mn is 16 bits, the One-Hot data is outputted with 32 bits in order to keep consistency with the other One-Hot data. In this case, 16 leading bits are fixed to “0.”

The other repair analysis circuit-attached RAM units Mv (v=2−(n−1)) are composed similarly, and One-Hot data OHv including a bit group of 32-bit configuration is outputted from an equivalent to the serializer 44, respectively.

In this way, among the One-Hot data OH1-OHn, the number of bits of bit groups is unified at the same number of 32 bits.

In the example illustrated in FIG. 23, a capture operation is carried out by the FAC circuit 43 for the row address signal of the address signal bist_ad [*] (bist_ad [6:2] in the present example) when the failure signal Sfail is set to “1.” For example, when “11101” (“29” in decimal) is captured as the fail address fail_address in the FAC circuit 43, this 5-bit data is converted into 32-bit One-Hot data (only a single “1” exists) after the end of the test by the serializer 44.

It may be possible to employ the configuration in which a down counter capable of count-down processing is employed as the serializer 44, and the fail address fail_address is inputted as an initial value. In this case, after loading the fail address fail_address, the serializer 44 outputs “0” serially whenever countdown is carried out, and outputs “1” only when the count value becomes “0.” After outputting “1”, the serializer 44 outputs “0” serially as many as the number of bits which satisfies the number of bits of the bit group of the One-Hot data OH1.

The n-input OR gate 45 inputs serially the One-Hot data OH1-OHn from a leading bit in units of bit, obtains the bitwise logical addition of n serial outputs, and outputs a bit group of 32-bit configuration composed of the logical addition as an output signal S45. This output signal S45 serves as comprehensive failure serial information sequentially obtained in units of bit from the logical addition of the One-Hot data OH1-OHn.

The one-or-more-bit error detector 46 verifies the output signal S45 for every bit, sets the repair necessity flag F1 to “1” when one or more bits having “1” is detected, otherwise, sets the repair necessity flag F1 to “0.”

The two-or-more-bit error detector 47 verifies the output signal S45 for every bit, sets the repair disenable flag F2 to “1” when two or more bits having “1” are detected, otherwise, sets the repair disenable flag F2 to “0.”

The sequential encoder 48 inputs the output signal S45 serially, and outputs a repair row address RRA which indicates the failure location based on a position where “1” is inputted in the output signal S45.

The semiconductor integrated circuit of Embodiment 8 of such configuration determines uniquely the repair row address RRA which is repairable, when the repair necessity flag F1=1 and the repair disenable flag F2=0. In this way, a repair possibility verification unit which detects the existence or nonexistence of a repair possibility is composed of the one-or-more-bit error detector 46, which sets the repair necessity flag F1, and the two-or-more-bit error detector 47, which sets the repair disenable flag F2.

As a result, when the repair necessity flag F1=1 and the repair disenable flag F2=0, the failure repair for the repair analysis circuit-attached RAM units M1-Mn can be practiced as a whole, by replacing the row address denoted by the repair row address RRA with the address of the repair memory, in a lump, to RAM 41 of the repair analysis circuit-attached RAM units M1-Mn. In this way, the sequential encoder 48 functions as a repair information acquiring unit which acquires repair information by obtaining a failure location on the basis of the output signal S45.

In the example illustrated in FIG. 23, when only the One-Hot data OH1 is “000-0100” and the One-Hot data OH2-OHn are “0” in all the bits, then, the repair necessity flag F1=1, the repair disenable flag F2=0, and the repair row address RRA=“11101” (“29” in decimal) are outputted. As a result, the failure repair for the repair analysis circuit-attached RAM units M1-Mn can be practiced as a whole, by carrying out the failure repair of the row address No. 29 in each of the repair analysis circuit-attached RAM units M1-Mn. The failure repair is carried out by supplying a replace address and a replace enable signal to RAM 41 of the repair analysis circuit-attached RAM units M1-Mn, with the use of a fuse circuit or a register which are not shown.

In the case of the example described above, as for the repair analysis circuit-attached RAM units M2-Mn other than the repair analysis circuit-attached RAM unit M1, the row address No. 29 which is not at fault in fact will be replaced by the redundancy memory. However, if the redundancy memory is normal, there will be no trouble in operation.

In this way, the semiconductor integrated circuit of Embodiment 8 acquires the output signal S45 which is comprehensive failure serial information. The comprehensive failure serial information is sequentially obtained from the logical addition in units of bit of the One-Hot data OH1-OHn as the plural pieces of failure serial information. Based on the output signal S45, the semiconductor integrated circuit of Embodiment 8 detects the existence or nonexistence of the repair possibility, and acquires the repair information by obtaining the failure location, with the use of the one-or-more-bit error detector 46, the two-or-more-bit error detector 47, and the sequential encoder 48.

Consequently, the semiconductor integrated circuit of Embodiment 8 can carry out failure repair in a lump to the repair analysis circuit-attached RAM units M1-Mn, and can attain the increased efficiency as much for the failure repair function.

In this case, the semiconductor integrated circuit of Embodiment 8 can carry out the repair of the failure row address to the repair analysis circuit-attached RAM units M1-Mn, based on the repair row address RRA.

### Embodiment 9

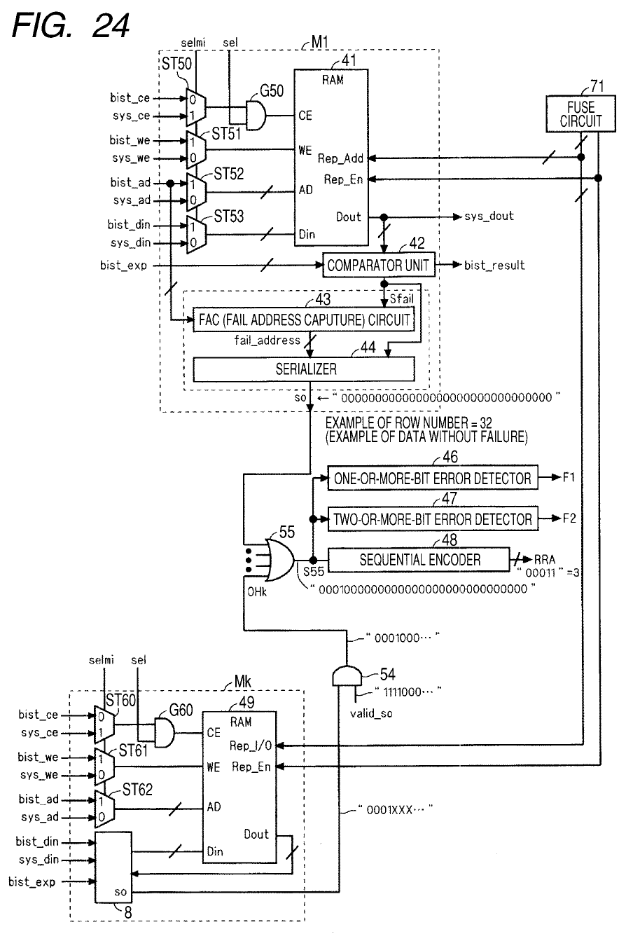

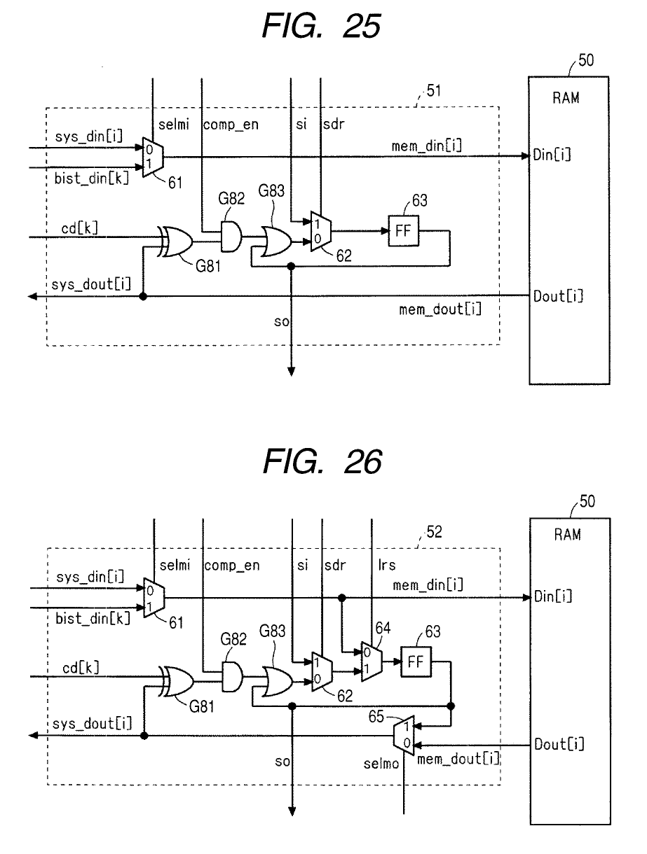

FIG. 24 is an explanatory diagram illustrating the configuration of a semiconductor integrated circuit having a failure analysis function, according to Embodiment 9 of the present invention.

As illustrated in FIG. 24, one unit including an AND gate 54, an OR gate 55, a one-or-more-bit error detector 46, a two-or-more-bit error detector 47, a sequential encoder 48, and a fuse circuit 71 is provided to n pieces of repair analysis circuit-attached RAM units M1-Mn.

The repair analysis circuit-attached RAM unit M1, same as in Embodiment 8 illustrated in FIG. 23, includes RAM 41, selectors ST50-ST53, a AND gate G50, a comparator unit 42, an FAC circuit 43, and a serializer 44.

The other repair analysis circuit-attached RAM units Mv (v=2−(n−1)) are composed similarly, and One-Hot data OHv is outputted from an equivalent to the serializer 44, respectively. However, a repair analysis circuit-attached RAM unit Mk with respect to an I/O bit is included in at least one of the repair analysis circuit-attached RAM units M1-Mn.

The repair analysis circuit-attached RAM unit Mk includes RAM 49, selectors ST60-ST62, an AND gate G60, and a data input/output controller 8. Although not shown, RAM 49 has a redundancy memory such as the spare memory column RMC illustrated in FIG. 4 of Embodiment 1, for example.

The selectors ST60-ST62 perform a function equivalent to the selectors ST50-ST52 of the repair analysis circuit-attached RAM unit M1, and the AND gate G60 performs a function equivalent to the AND gate G50. The data input/output controller 8 is coupled to a data input Din and a data output Dout, and performs a function equivalent to the data input/output controller 53 illustrated in FIG. 27. Consequently, the failure analysis result of an I/O bit can be serially outputted from the serial data output So of the data input/output controller 8.

The AND gate 54 receives the output of the serial data output So of the data input/output controller 8 at one input, and receives a valid bit indication serial signal valid_so at another input. The valid bit indication serial signal valid_so has “1” for the number of the valid input/output bits of the data input/output controller 8, and has “0” serially outputted henceforth.

Consequently, the AND gate 54 can output the One-Hot data OHk which indicates “1” only for the failure I/O bit position of the repair analysis circuit-attached RAM unit Mk. Assume that the number of the valid bits of RAM 49 is 4 and the failure I/O bit number is 3, for example. In this case, the output from the serial data output So of the data input/output controller 8 becomes “0001xxx—” (x is unfixed). On the other hand, the valid bit indication serial signal valid_so becomes “11110000—.” As a result, the One-Hot data OHk becomes “00010000—.”

In this way, same as in Embodiment 8, among the One-Hot data OH1-OHn, the number of bits of bit groups is unified at the same number of 32 bits.

The n-input OR gate 55 inputs serially the One-Hot data OH1-OHn in units of bit from the leading bit, and outputs serially the bit group of 32 bits of n pieces of OR operation outputs as the output signal S55. This output signal S55 serves as comprehensive failure serial information sequentially obtained in units of bit from the logical addition of the One-Hot data OH1-OHn.

The one-or-more-bit error detector 46 verifies the output signal S55 for every bit, sets the repair necessity flag F1 to “1” when one or more bits having “1” is detected, otherwise, sets the repair necessity flag F1 to “0.”

The two-or-more-bit error detector 47 verifies the output signal S55 for every bit, sets the repair disenable flag F2 to “1” when two or more bits having “1” are detected, otherwise, sets the repair disenable flag F2 to “0.”

The sequential encoder 48 inputs serially the output signal S55, and outputs the repair row address RRA which indicates the failure location. The repair row address RRA means a repair I/O bit position in the case of the repair analysis circuit-attached RAM unit Mk.

The semiconductor integrated circuit of Embodiment 9 of such configuration determines uniquely the repair row address RRA which is repairable, when the repair necessity flag F1=1 and the repair disenable flag F2=0.

That is, the fuse circuit 71 outputs the row address denoted by the repair row address RRA as the replace address Rep_Add, based on the repair row address RRA, sets the replace enable signal Rep_En to “1” (valid), and gives the replace address Rep_Add to the repair analysis circuit-attached RAM units M1-Mn. As a result, the address denoted by the replace address Rep_Add can be repaired, in a lump, in the repair analysis circuit-attached RAM units M1-Mn. These replace address Rep_Add and replace enable signal Rep_En correspond to the repair control signal (rai1 [*], ren1, rai2 [*], ren2, rai3 [*], ren3, etc.) shown in Embodiment 1-Embodiment 4.

About the repair analysis circuit-attached RAM unit Mk, the replace address Rep_Add is inputted as the replace I/O bit number Rep_I/O.

In the example illustrated in FIG. 24, when only the One-Hot data OHk is “00010000—” and the other One-Hot data have “0” for all the bits, then, the repair necessity flag F1=1, the repair disenable flag F2=0, and the repair row address RRA=“00011” (“3” in decimal) are outputted. As a result, in RAM 41 of each of the repair analysis circuit-attached RAM units M1-Mn, the failure repair of the row address (the replace address Rep_Add) of No. 3 is carried out from the fuse circuit 71. Accordingly, the failure repair of the repair analysis circuit-attached RAM units M1-Mn as a whole can be practiced. However, for the RAM 49 of the repair analysis circuit-attached RAM unit Mk, the repair of the I/O bit of the I/O bit number 3 (the replace I/O bit number Rep_I/O) is carried out.

In the case of the example described above, the row address No. 3 which is not at fault in fact will be replaced by the redundancy memory, for the repair analysis circuit-attached RAM units M1-Mn other than the repair analysis circuit-attached RAM unit Mk. However, if the redundancy memory is normal, there will be no trouble in operation.

On the other hand, as in the example of Embodiment 8 illustrated in FIG. 23, when only the One-Hot data OH1 is “000-0100” and the One-Hot data OH2-OHn are “0” in all the bits, then, the repair necessity flag F1=1, the repair disenable flag F2=0, and the repair row address RRA=“11101” (“29” in decimal) are outputted. As a result, the failure repair for the repair analysis circuit-attached RAM units M1-Mn can be practiced as a whole, by carrying out the failure repair of the row address No. 29 in each of the repair analysis circuit-attached RAM units M1-Mn. However, for RAM 49 of the repair analysis circuit-attached RAM unit Mk, the repair of the I/O bit of the I/O bit number 1 (because the value of lower 2 bits of 29 is “01”) is carried out.

In the case of the example described above, the row address No. 29 which is not at fault in fact will be replaced by the redundancy memory, for the repair analysis circuit-attached RAM units M2-Mn other than the repair analysis circuit-attached RAM unit M1. However, if the redundancy memory is normal, there will be no trouble in operation.

In this way, in addition to the effect of the semiconductor integrated circuit of Embodiment 8, the semiconductor integrated circuit of Embodiment 9 also produces the effect that the repair of the input/output bit of RAM 49 of the repair analysis circuit-attached RAM unit Mk can also be practiced, together with the repair of the failure row address to RAM 41 of the repair analysis circuit-attached RAM units M1-Mn.

The present invention is widely applicable to LSI in which plural RAMs (memory circuit) are mounted. Especially, the present invention is suitable for application to LSI including RAM to which the redundancy technique for the improvement in the yield is applied, and can perform failure repair using the generated failure information.

1. A semiconductor integrated circuit comprising:
a plurality of memory circuits each including a redundancy memory and each having a data input/output function of at least one bit;
a plurality of comparators provided corresponding to the plural memory circuits and operable to obtain a comparison result by comparing data output of the plural memory circuits with an expectation value;
a plurality of result latch units provided corresponding to the plural comparators and operable to store a comparison result of the plural comparators as a plurality of latch data groups, the plural result latch units being mutually coupled in series in the case of a shift mode so as to perform shift operation among the plural latch data groups and being able to perform serial output externally as a repair analysis scan-path signal;
a repair analysis circuit operable to sequentially take in the repair analysis scan-path signal in the case of the shift mode, and operable to obtain repair analysis information indicative of the existence or nonexistence of necessity of repair and a failure location requiring repair with respect to the plural memory circuits, based on the repair analysis scan-path signal; and
a repair decoder operable to perform repair control to replace the failure location with the redundancy memory to a memory circuit requiring repair among the plural memory circuits, based on repair control information related to the repair analysis information.

2. The semiconductor integrated circuit according to claim 1,
wherein the repair analysis information includes a plural pieces of partial repair analysis information indicative of the existence or nonexistence of necessity of repair and a failure location requiring repair with respect to each of the plural memory circuits,
wherein the repair control information includes a plural pieces of partial repair control information corresponding to the plural memory circuits, each of the plural pieces of partial repair control information indicating the existence or nonexistence of necessity of repair and a failure location requiring repair with respect to the corresponding memory circuit, and
wherein the repair decoder includes a plurality of repair decoders which are provided corresponding to the plural memory circuits and perform repair control of the corresponding memory circuit, based on the corresponding partial repair control information.

3. The semiconductor integrated circuit according to claim 2, further comprising:
a test control circuit operable to output, to the repair analysis circuit, a control signal including a reset signal indicating switching, at the time of switching among the plural latch data groups in the repair analysis scan-path signal.

4. The semiconductor integrated circuit according to claim 3, further comprising:
a dummy latch unit inserted between the plural result latch units and operable to store dummy data,
wherein the dummy latch unit is coupled between the plural result latch units in the case of the shift mode, allowing the shift operation to be performed to the plural latch data groups and the dummy data, and
wherein the test control circuit outputs, to the plural result latch units, a shift operation signal indicating the existence and nonexistence of the shift operation, outputs the reset signal while the dummy data is outputted as the repair analysis scan-path signal, and further outputs, as the control signal, a scan-path invalid indication signal indicating invalidation of the repair analysis scan-path signal.

5. The semiconductor integrated circuit according to claim 2,
wherein the repair analysis information includes one-bit failure information indicative of the existence and nonexistence of failure at one or more places with respect to each of the plural memory circuits.

6. The semiconductor integrated circuit according to claim 5,
wherein the repair analysis information further includes multibit failure information indicative of the existence and nonexistence of failure at two or more places with respect to each of the plural memory circuits.

7. The semiconductor integrated circuit according to claim 1,
wherein the repair analysis information includes information indicative of the existence or nonexistence of necessity of repair and the failure location with respect to the whole plural memory circuits, and
wherein the repair decoder performs, to one memory circuit among the plural memory circuits, repair control of the memory circuit based on the repair control information.

8. The semiconductor integrated circuit according to claim 7, further comprising:
a test control circuit operable to output, to the plural result latch units, a shift operation signal indicative of the existence and nonexistence of the shift operation.

9. The semiconductor integrated circuit according to claim 7,
wherein the repair analysis information includes one-bit failure information indicative of the existence and nonexistence of failure at one or more places in the whole plural memory circuits.

10. The semiconductor integrated circuit according to claim 9,
wherein the repair analysis information further includes multibit failure information indicative of the existence and nonexistence of failure at two or more places in the whole plural memory circuits.

11. The semiconductor integrated circuit according to claim 1,
wherein the plural memory circuits includes:
a plurality of first-class memory circuits classified as a first group; and
a plurality of second-class memory circuits classified as a second group,
wherein the repair analysis information includes: a plural pieces of partial repair analysis information for the first group, indicative of the existence and nonexistence of necessity of repair and the failure location with respect to each of the plural first-class memory circuits; and repair analysis information for the second group, indicative of the existence and nonexistence of necessity of repair and the failure location with respect to the whole plural second-class memory circuits,
wherein the repair control information includes a plural pieces of partial repair control information for the first group, related to the plural pieces of partial repair analysis information for the first group and corresponding to the plural first-class memory circuits, the plural pieces of partial repair control information for the first group being indicative of the existence and nonexistence of necessity of repair and the failure location with respect to each of the first-class memory circuit,
wherein the repair control information further includes repair control information for the second group, related to the repair analysis information for the second group and corresponding to the whole plural second-class memory circuits, the repair control information for the second group being indicative of the existence and nonexistence of necessity of repair and the failure location with respect to the whole plural second-class memory circuits, and
wherein the repair decoder includes:
a plurality of repair decoders for the first group which are provided corresponding to the plural first-class memory circuits and perform repair control of the corresponding first-class memory circuit based on the respectively corresponding partial repair control information; and
a repair decoder for the second group which is provided corresponding to the whole plural second-class memory circuits and performs repair control to one second-class memory circuit among the plural second-class memory circuits based on the repair control information for the second group.

12. The semiconductor integrated circuit according to claim 11,
wherein the plural comparators includes:
a plurality of comparators for the first group which are provided corresponding to the plural first-class memory circuits and obtain a first comparison result by comparing data output of the plural first-class memory circuits with an expectation value; and
a plurality of comparators for the second group which are provided corresponding to the plural second-class memory circuits and obtain a second comparison result by comparing data output of the plural second-class memory circuits with an expectation value,
wherein the plural latch data groups include:
a plurality of result latch units for the first group which are provided corresponding to the plural comparators for the first group and store comparison results of the plural comparators for the first group as a plurality of latch data groups for the first group; and
a plurality of result latch units for the second group which are provided corresponding to the plural comparators for the second group and store comparison results of the plural comparators for the second group as a plurality of latch data groups for the second group,
wherein the plural result latch units for the first group are mutually coupled in series in the case of a shift mode, the plural result latch units for the second group are mutually coupled in series in the case of a shift mode, and a serial coupling is established between the plural result latch units for the first group and the plural result latch units for second group, allowing the whole plural latch data groups for the first and the second group to perform shift operation and to perform serial output externally as the repair analysis scan-path signal, and
wherein the repair analysis circuit obtains the repair analysis information for the first group to the first-class memory circuits and the repair analysis information for the second group to the second-class memory circuits, based on the repair analysis scan-path signal.

13. The semiconductor integrated circuit according to claim 11,
wherein the plural comparators includes:
a plurality of comparators for the first group which are provided corresponding to the plural first-class memory circuits and obtains a first comparison result by comparing data output of the plural first-class memory circuits with an expectation value; and
a plurality of comparators for the second group which are provided corresponding to the plural second-class memory circuits and obtains a second comparison result by comparing data output of the plural second-class memory circuits with an expectation value,
wherein the plural latch data groups includes:
a plurality of result latch units for the first group which are provided corresponding to the plural comparators for the first group and stores comparison results of the plural comparators for the first group as a plurality of latch data groups for the first group; and
a plurality of result latch units for the second group which are provided corresponding to the plural comparators for the second group and stores comparison results of the plural comparators for the second group as a plurality of latch data groups for the second group,
wherein the plural result latch units for the first group are mutually coupled in series in the case of a shift mode, the plural result latch units for the second group are mutually coupled in series in the case of a shift mode, and the plural latch data groups for the first group and the plural latch data groups for the second group perform shift operation independently and yield respectively serial output as a scan-path signal for the first group and as a scan-path signal for the second group,
wherein the plural latch data groups further includes:
a selection circuit operable to selectively output one scan-path signal out of the scan-path signal for the first group and the scan-path signal for the second group, as the repair analysis scan-path signal, and
wherein the repair analysis circuit obtains selectively the repair analysis information for the first group and the repair analysis information for the second group based on the repair analysis scan-path signal.

14. A semiconductor integrated circuit comprising:
a memory circuit including a redundancy memory and having a data input/output function of predetermined number of bits; and
a data input/output controller operable to control data input/output of the predetermined number of bits in the memory circuit,
wherein the data input/output controller includes:
a one-bit input/output controller of predetermined number of bits, provided corresponding to the data input/output of the predetermined number of bits and having a comparison circuit of predetermined number of bits which obtains sequentially a comparison result of the predetermined number of bits by comparing each data output of the predetermined number of bits of the memory circuit with an expectation value;
an encoding circuit operable to sequentially generate encoded data of a smaller number of compressed bits than the predetermined number of bits, based on the comparison result of the predetermined number of bits; and
a capture circuit having a latch circuit of the number of compressed bits, the capture circuit being operable to sequentially receive the encoded data of the number of compressed bits and operable to latch, to the latch circuit of the number of compressed bits, one piece of encoded data having the number of compressed bits and satisfying a predetermined condition,
wherein the encoded data of the number of compressed bits is capable of indicating at least first failure information on non-existence of a failure bit and second failure information on existence of one-bit failure and the bit location, with respect to the data input/output of the predetermined number of bits.

15. The semiconductor integrated circuit according to claim 14,
wherein the encoded data of the number of compressed bits is further capable of indicating third failure information on two or more-bit failure.

16. The semiconductor integrated circuit according to claim 15,
wherein the latch circuit of the number of compressed bits is coupled to perform shift operation and to output serially the encoded data of the number of compressed bits.

17. The semiconductor integrated circuit according to claim 16,
wherein the predetermined condition includes a condition that, when the encoded data of the number of compressed bits indicates the second failure information, the second failure information is latched more preferentially than the first failure information indicated by the encoded data of the number of compressed bits, and that, when the encoded data of the number of compressed bits sequentially obtained indicates the second failure information plural times, the second failure information indicated first is latched more preferentially than others.

18. The semiconductor integrated circuit according to claim 16,
wherein the predetermined condition includes:
a condition that, when the encoded data of the number of compressed bits indicates the third failure information, the third failure information is latched more preferentially than the first failure information and the second failure information, indicated by the encoded data of the number of compressed bits.

19. A semiconductor integrated circuit comprising:
a memory circuit having a data input/output function of a predetermined number of bits; and
a data input/output controller operable to control data input/output of the predetermined number of bits in the memory circuit,
wherein the data input/output controller includes:
at least one selection circuit which is provided corresponding to data output of the predetermined selection number of two or more among the data output of the predetermined number of bits, and selects, as selected data output, one of the data output of the predetermined selection number based on a data output selection signal; and
at least one comparison circuit which compares the selected data output with an expectation value to obtain a comparison result of at least one bit.

20. The semiconductor integrated circuit according to claim 19,
wherein the data input/output controller further includes:
a latch unit operable to latch the comparison result of at least one bit.

21. The semiconductor integrated circuit according to claim 19,
wherein the at least one selection circuit includes a plurality of selection circuits,
wherein the at least one comparison circuit includes a plurality of comparison circuits which obtain a plurality of comparison results by comparing each of the plural selected data outputs with an expectation value, and
wherein the data input/output controller further includes:
a comprehensive comparison result output unit operable to receive the plural comparison results and to output a comprehensive comparison result obtained by determining whether or not at least one comparison result among the plural comparison results indicates a failure bit; and
a latch unit operable to latch the comprehensive comparison result.

22. A semiconductor integrated circuit comprising:
a plurality of memory circuits having a chip enable input, a write enable input, an address input, and a data input; and
a non-test-target disenabling means operable to disenable the chip enable input to a memory circuit as a non-test-target, in sequentially testing the plural memory circuits by group, and operable to assign a fixed signal to at least one of the write enable input, the address input, and the data input.

23. A semiconductor integrated circuit comprising:
a plurality of memory units each including a memory circuit and having a failure repair analyzing function to the memory circuit, the plural memory units outputting plural pieces of failure serial information including a bit group indicating a failure location in the memory circuit by “1” and the remaining locations by “0”, and the number of bits of the bit group in the plural pieces of failure serial information being unified by the same number of bits;
a comprehensive failure determination unit operable to receive the plural pieces of failure serial information in units of bit and operable to output comprehensive failure serial information sequentially obtained by logical addition of the plural pieces of failure serial information in units of bit;
a repair possibility verification unit operable to detect the existence or non-existence of repair possibility, based on the comprehensive failure serial information; and
a repair information acquiring unit operable to acquire repair information by obtaining a failure location based on the comprehensive failure serial information.

24. The semiconductor integrated circuit according to claim 23,
wherein the failure location includes a failure row-address location of the corresponding memory circuit.

25. The semiconductor integrated circuit according to claim 24,
wherein the failure location further includes a failure input/output bit location of the corresponding memory circuit.

26. The semiconductor integrated circuit according to claim 4,
wherein the repair analysis information includes one-bit failure information indicative of the existence and nonexistence of failure at one or more places with respect to each of the plural memory circuits.

27. The semiconductor integrated circuit according to claim 26,
wherein the repair analysis information further includes multibit failure information indicative of the existence and nonexistence of failure at two or more places with respect to each of the plural memory circuits.

28. The semiconductor integrated circuit according to claim 8,
wherein the repair analysis information includes one-bit failure information indicative of the existence and nonexistence of failure at one or more places in the whole plural memory circuits.

29. The semiconductor integrated circuit according to claim 28,
wherein the repair analysis information further includes multibit failure information indicative of the existence and nonexistence of failure at two or more places in the whole plural memory circuits.

30. The semiconductor integrated circuit according to claim 17,
wherein the predetermined condition includes:
a condition that, when the encoded data of the number of compressed bits indicates the third failure information, the third failure information is latched more preferentially than the first failure information and the second failure information, indicated by the encoded data of the number of compressed bits.
